(19) United States
(12) Patent Application Publication
(10) Pub. No.: US 2012/0305049 A1
(43) Pub. Date: Dec. 6, 2012

(54) SOLAR CELL AND SOLAR CELL MANUFACTURING METHOD

(75) Inventors: Shigenori Yuya, Ashigara-kami-gun (JP); Keigo Sato, Ashigara-kami-gun (JP); Ryuichi Nakayama, Ashigara-kami-gun (JP); Ryozo Kaito, Ashigara-kami-gun (JP); Naoki Murakami, Ashigara-kami-gun (JP)

(73) Assignee: FUJIFILM CORPORATION, Minato-ku, Tokyo (JP)

(21) Appl. No.: 13/574,445

(22) PCT Filed: Jan. 18, 2011
(86) PCT No.: PCT/JP2011/000221

§ 371 Date: Jul. 20, 2012

(30) Foreign Application Priority Data
Jan. 21, 2010 (JP) 2010-011054
Nov. 24, 2010 (JP) 2010-261396

(51) Int. Cl. H01L 31/042; H01L 31/18

(52) U.S. Cl. 136/244; 438/93; 257/E31.003

(57) ABSTRACT

A solar cell of a module type in which thin-film solar cells having a light absorbing layer made of a compound semiconductor are joined in series on a single substrate. The substrate includes a base made of a ferritic stainless steel, an aluminum layer formed on at least one surface of the base, and an insulation layer having a porous structure obtained by anodizing a surface of the aluminum layer. The insulation layer exhibits compressive stress at room temperature.

### TECHNICAL FIELD

The present invention relates to a solar cell which has a light absorbing layer made of a compound semiconductor such as a CIGS compound on a metallic substrate having an insulation layer formed therein and exhibits excellent insulation properties and photoelectric conversion efficiency. The invention also relates to a method of manufacturing such a solar cell.

### BACKGROUND ART

Silicon solar cells using bulky monocrystalline or polycrystalline silicon or thin-film amorphous silicon have conventionally been mainly employed but compound semiconductor solar cells which do not depend on silicon are recently under research and development.

Bulky materials such as GaAs and thin-film materials such as CIS (Cu—In—Se) and CIGS (Cu—In—Ga—Se) including a group Ib element, a group IIIb element, and a group VIb element are known for the compound semiconductor solar cells. CIS and CIGS materials are reported to have high optical absorptance and high photoelectric conversion efficiency.

At present, glass substrates are mainly used for solar cells but use of flexible metallic substrates is under investigation.

There is a possibility that compound thin-film solar cells using metallic substrates can be applied to a wide variety of applications compared to ordinary ones using glass substrates based on the characteristics such as the lightweight properties and flexibility of the substrates. In addition, from the viewpoint that the metallic substrates can withstand high-temperature processes, the light absorbing layer can be formed at high temperatures to hold promise for higher efficiency of solar cells together with improved photoelectric conversion properties.

Solar cells are connected in series on a single substrate and integrated into a solar cell module, whereby the efficiency of the module can be improved. In cases where a metallic substrate is used in this process, it is necessary to form an insulation layer on the metallic substrate and provide a semiconductor circuit layer for photoelectric conversion.

For example, Patent Literature 1 describes that iron materials such as stainless steels are used for the solar cell substrate and an insulation layer is formed by coating the substrate with silicon oxide or aluminum oxide by a vapor-phase deposition technique such as CVD or a liquid-phase deposition technique such as a sol-gel method.

However, these techniques easily cause pinholes and cracks and have essential problems in consistently preparing a large-area thin-film insulation layer.

On the other hand, in the case of aluminum (Al) being used for the solar cell substrate, an insulation film having no pinholes and exhibiting good adhesion is obtained by forming an anodized film on its surface of substrate.

Therefore, as described in Patent Literature 2, solar cell modules using a substrate obtained by forming an anodized film serving as the insulation layer on a surface of an aluminum substrate are under active research.

As described in Non-Patent Literature 1, cracks are known to be formed in the anodized film formed at the aluminum surface by heating to a temperature of 120 deg C. or more.

However, in order to achieve high-quality photoelectric conversion efficiency, the light absorbing layer made of a compound semiconductor and particularly of a CIGS compound semiconductor is to be deposited at a higher film deposition temperature and the film deposition temperature is typically at least 500 deg C.

Cracking or delamination of the anodized film may occur during the formation of the light absorbing layer or upon cooling after the film deposition when a substrate having an anodized aluminum film serving as the insulation layer is used for the substrate of the solar cell having the light absorbing layer made of a compound semiconductor.

Once cracking occurs, the insulation properties are deteriorated and particularly the leakage current is increased, leading to unsatisfactory photoelectric conversion efficiency. Dielectric breakdown may also occur.

What is more, aluminum softens at around 200 deg C. and therefore an aluminum substrate having experienced a temperature equal to or larger than this value has an extremely small strength and easily undergoes permanent deformation (plastic deformation) such as creep deformation or buckling deformation.

Therefore, handling of solar cells using aluminum substrates is to be strictly restricted also during the manufacture thereof. This makes it difficult for such solar cells using aluminum substrates to be applied to outdoor solar cell units.

On the other hand, Patent Literature 3 discloses using for the substrate of a photovoltaic device including an amorphous silicon layer serving as a conventional light absorbing layer (photovoltaic element), an insulation layer-containing metallic substrate obtained by forming an aluminum layer on a surface of an alloy steel sheet by hot dip aluminum coating and forming an insulation layer on a surface of the aluminum layer by anodization.

Patent Literature 3 and Patent Literature 4 describe that, by preparing a spring steel sheet or an alloy steel sheet such as SUS304 for the base, the alloy steel sheet does not soften even if the aluminum layer softens under heating at 200 to 300 deg C. during the step such as deposition of amorphous silicon, whereby the elastic force or other mechanical strength can be maintained over the whole of the substrate.

### CITATION LIST

### Patent Literature

[PATENT LITERATURE 1] JP 2001-339081 A
[PATENT LITERATURE 2] JP 2000-49372 A
[PATENT LITERATURE 3] JP 62-89369 A
[PATENT LITERATURE 4] JP 62-49673 A

### Non-Patent Literature

[NON-PATENT LITERATURE 1] Masashi KAYASHIMA, Masakatsu MUSHIRO, Tokyo Metropolitan Industrial Technology Research Institute, Research Report No. 3, December 2000, p. 21.

### SUMMARY OF INVENTION

### Technical Problems

As described above, Patent Literature 3 and Patent Literature 4 disclose a structure which can also withstand heating at a film deposition temperature of the light absorbing layer ranging from 200 to 300 deg C. by using a substrate having an insulation layer obtained by providing an aluminum material on an alloy steel sheet and anodizing the aluminum material when preparing a device comprising amorphous silicon serving as the light absorbing layer.

However, in cases where a compound semiconductor which is now under investigation is used for the light absorbing layer, the film deposition temperature of the light absorbing layer is to be further increased to achieve high-quality photoelectric conversion efficiency. In general, a temperature of 500 deg C. or more is suitable. Therefore, a substrate of a structure-capable of withstanding high temperatures of 500 deg C. or more is required.

In addition, in the case of a solar cell which has a light absorbing layer made of a compound semiconductor and particularly a light absorbing layer having a chalcopyrite structure including a group Ib element, a group IIIb element, and a group VIb element, cracking and delamination of the anodized film cannot be suppressed and satisfactory photoelectric conversion efficiency cannot be obtained by merely relying on the structure in which a metallic base making up a substrate with aluminum and an insulation layer (anodized layer) is highly resistant to heating at the film deposition temperature of the light absorbing layer.

It is therefore an object of the present invention to overcome the above problems associated with the prior art and provide a solar cell of a module type in which thin-film solar cells having a light absorbing layer made of a compound semiconductor are joined in series on a substrate having an Al-anodized insulation layer formed therein, wherein the substrate is capable of preventing crack occurrence on the insulation layer and maintaining favorable insulation properties, mechanical strength, and flexibility even with a high-temperature heat history of 500 deg C. or more, which is preferred for deposition of the light absorbing layer, and in particular allows the manufacture of a large-area solar cell of a module type capable of power system linkage using a roll-to-roll process; and a solar cell manufacturing method free of crack occurrence and partial delamination of components and capable of suppressing time degradation.

### Solution to Problems

In order to achieve the above objects, the invention is to provide a solar cell of a module type, comprising: a substrate; and thin-film solar cells joined in series on the substrate, wherein each of the thin-film solar cells has a light absorbing layer made of a compound semiconductor, the substrate includes a base made of ferritic stainless steel, an aluminum layer formed on at least one surface of the base, and an insulation layer having a porous structure obtained by anodizing a surface of the aluminum layer, and the insulation layer exhibits compressive stress at room temperature.

In the solar cell of the present invention, the compressive stress of the insulation layer ranges preferably from 4 MPa to 400 MPa. Preferably, a Young's modulus of the insulation layer ranges from 50 GPa to 130 GPa.

Further, preferably, a alloy layer made of at least one metal of the ferritic stainless and aluminum exists in an interface between the base and the aluminum layer, and a thickness of the alloy layer ranges from 0.01 micrometers to 10 micrometers.

Further, the alloy layer is preferably made of an alloy of a composition expressed by Al₃X (where X is at least one kind of element selected from Fe and Cr). Preferably, a thickness of the aluminum layer ranges from 0.1 micrometers to a thickness of the base. Preferably, a thickness of the insulation layer ranges from 2 micrometers to 50 micrometers.

Further, the light absorbing layer preferably comprises at least one kind of compound semiconductor having a chalcopyrite structure comprising a group Ib element, a group IIIb element, and a group VIb element, and preferably comprises a CIGS compound.

Preferably, the thin-film solar cells further includes back electrodes made of molybdenum, respectively, and the insulation layer contain an alkali metal-containing compound, the solar cell further includes compound layers made of the alkali metal-containing compound disposed between the back electrodes and the insulation layer, or both. Preferably, the alkali metal-containing compound is a compound made primarily of silicon oxide and containing sodium oxide.

The invention also provides a method of manufacturing a solar cell, comprising: a first step of forming a substrate, the first step comprising: forming a aluminum layer on a surface of base made of ferritic stainless steel by pressurizing and bonding, and anodizing the aluminum layer under a predetermined condition to form an insulation layer that exhibits compressive stress at room temperature; a second step of forming back electrodes on the insulation layer of the substrate; a third step of forming light absorbing layers made of a compound semiconductor on the back electrodes at a film deposition temperature of 500 deg C. or more, respectively; and a fourth step of forming upper electrodes on the light absorbing layers, respectively.

In the method of manufacturing a solar cell of the present invention It is preferable that the method further comprise a step of allowing Na to contain into the insulation layer layer between the first step and the second step. The anodizing step is preferably achieved by electrolysis in an electrolytic solution of a temperature of 50 deg C. or more or an aqueous solution of a temperature of 50 deg C. or more, the electrolytic solution having an acid dissociation constant of 2.5 to 3.5 at a temperature of 25 deg C. The ferritic stainless steel and aluminum are preferably unified by pressurizing and bonding.

Further, the step of forming an insulation layer through anodization of the aluminum is preferably achieved by electrolysis in a solution of a temperature of 50 deg C. or more or an aqueous solution of a temperature of 50 deg C. or more.

The invention also provides a method of manufacturing a solar cell, comprising: a first step of forming a substrate, the first step comprising: forming a aluminum layer on a surface of base made of a ferritic stainless steel by pressurizing and bonding, anodizing the aluminum layer to form a first insulation layer, and subjecting the thus formed first insulation layer to a heat treatment at a heating temperature of 600 deg C. or less to form a second insulation layer that exhibits compressive stress at room temperature; a second step of forming back electrodes on the insulation layer of the substrate, respectively; a third step of forming light absorbing layers made of a compound semiconductor on the back electrodes at a film deposition temperature of 500 deg C. or more, respectively; and a fourth step of forming upper electrodes on the light absorbing layers, respectively.

Preferably, a heat treatment condition of the heat treatment subjecting step comprises a heating temperature of 100 to 600 deg C. and a holding time of 1 second to 10 hours.

The method preferably includes a step of forming a sodium-containing layer on the insulation layer or the insulation layer containing sodium.

Preferably, the substrate includes the base, the aluminum layer formed on the base and the insulation layer formed on the aluminum layer, and the heat treatment is performed in an atmosphere containing an oxygen.

In the manufacturing method, the back electrodes are preferably made of molybdenum and the method preferably comprises at least one step selected from: introducing an alkali metal-containing compound in the anodized film prior to formation of the back electrodes; forming a layer of the alkali metal-containing compound on a surface of the substrate; and introducing the alkali metal-containing compound in the anodized film and forming the layer of the alkali metal-containing compound on the surface of the substrate.

Further, the light absorbing layer preferably comprise a CIGS compound semiconductor, and the CIGS compound semiconductor is preferably formed by vapor-phase deposition. In such a case, the CIGS compound semiconductor is preferably formed as a CIGS layer by first evaporating four elements Cu, In, Ga, and Se onto each of the back electrodes, and in a following second phase, evaporating three elements In, Ga, and Se, excluding Cu.

Further, the ferritic stainless steel is preferably chrome steel that contain 17 mass % chrome, and the light absorbing layers are preferably formed under a condition expressed as a following expression (1), when Y is a temperature (deg C) and x is a time (minutes),

Y≦670−72.5 Log x (1).

Further, the ferritic stainless steel is preferably chrome steel that contain 30 mass % chrome, and the light absorbing layers are preferably formed under a condition expressed as a following expression (2), when Y is a temperature (deg C) and x is a time (minutes),

Y≦683−72.5 Log x (2).

### Advantageous Effects of Invention

The solar cell of the invention is a module type in which thin-film solar cells including a light absorbing layer (photoelectric conversion layer) made of a compound semiconductor such as CIGS are joined in series on a single substrate. The substrate used has an aluminum (Al) layer formed on a surface of a metallic base and an anodized aluminum film serving as an insulation layer. A ferritic stainless steel is used for the base of the substrate.

According to the solar cell of the invention in which a ferritic stainless steel is used for the base, cracking and delamination of the anodized film serving as the insulation layer can be suppressed even if the light absorbing layer is formed at a high temperature of 500 deg C. or more, whereby good insulation properties can be maintained.

In cases where an austenitic stainless steel or a low-carbon steel is used for the metallic base of the substrate of the same structure, the light absorbing layer may partially come off in the shape of spots or have cracks, leading to a decrease in the conversion efficiency of the solar cell. In contrast, the solar cell of the invention which uses a ferritic stainless steel for the base can suppress occurrence of such partial peeling, whereby the solar cell obtained has good conversion efficiency.

As described above, the invention is capable of maintaining high insulation properties and a high strength even after the step at a temperature of 500 deg C. or more. In other words, a manufacturing step at a high temperature of 500 deg C. or more is possible and the light absorbing layer made of a compound semiconductor can be formed at a film deposition temperature of 500 deg C. or more.

The compound semiconductor making up the light absorbing layer should be formed at a high temperature so that photoelectric conversion properties may be improved. Therefore, according to the invention, a solar cell having a light absorbing layer with improved photoelectric conversion properties can be obtained by film deposition at a temperature of 500 deg C. or more.

Moreover, the invention is capable of suppressing cracking and partial peeling of the anodized film serving as the insulation layer and the light absorbing layer even in a case where the solar cell is manufactured by a roll-to-roll process and a bending force is repeatedly applied by the rollers onto the substrate and the solar cell during manufacturing. As a result, a sound solar cell that is free of cracking and partial peeling of the substrate and light absorbing layer can be achieved.

Furthermore, since the invention can suppress cracking and partial peeling of the anodized film serving as the insulation layer and the light absorbing layer as described above even in a case where a large-area solar cell capable of power system linkage is subjected to thermal strain cycle due to day and night temperature difference, time degradation is suppressed, making it possible to achieve a solar cell with high long-term reliability.

### BRIEF DESCRIPTION OF DRAWINGS

FIG. 1A is a cross-sectional view schematically showing an example of a substrate used for a solar cell of the embodiment of the invention.

FIG. 1B is a cross-sectional views schematically showing an example of a substrate used for a solar cell of the embodiment of the invention.

FIG. 2 is a cross-sectional view schematically showing the solar cell of the embodiment of the invention.

FIG. 3A is a view showing an image processed photograph taken of the cross-section of the substrate.

FIG. 3B is a view showing an image processed photograph taken of the cross-section of the substrate.

FIG. 3C is a view showing an image processed photograph taken of the cross-section of the substrate.

FIG. 3D is a view showing an image processed photograph taken of the cross-section of the substrate.

FIG. 3E is a view showing an image processed photograph taken of the cross-section of the substrate.

FIG. 4 is a graph schematically showing the heat treatment conditions under which the thickness of the intermetallic compound of the substrate provided with an aluminum layer reaches 10 micrometers.

### DESCRIPTION OF EMBODIMENTS

The solar cell and the solar cell manufacturing method of the invention are described below in detail with reference to preferred embodiments shown in the accompanying drawings.

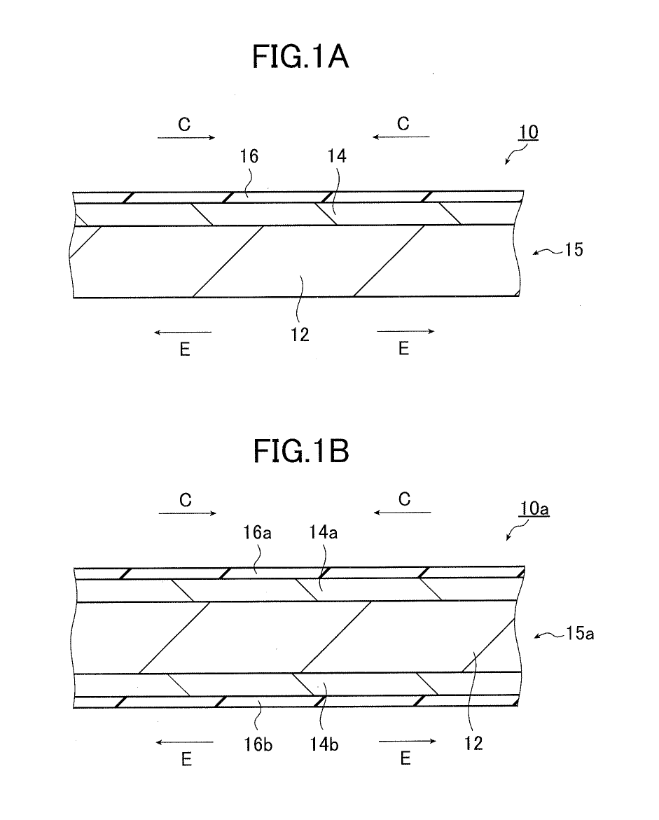

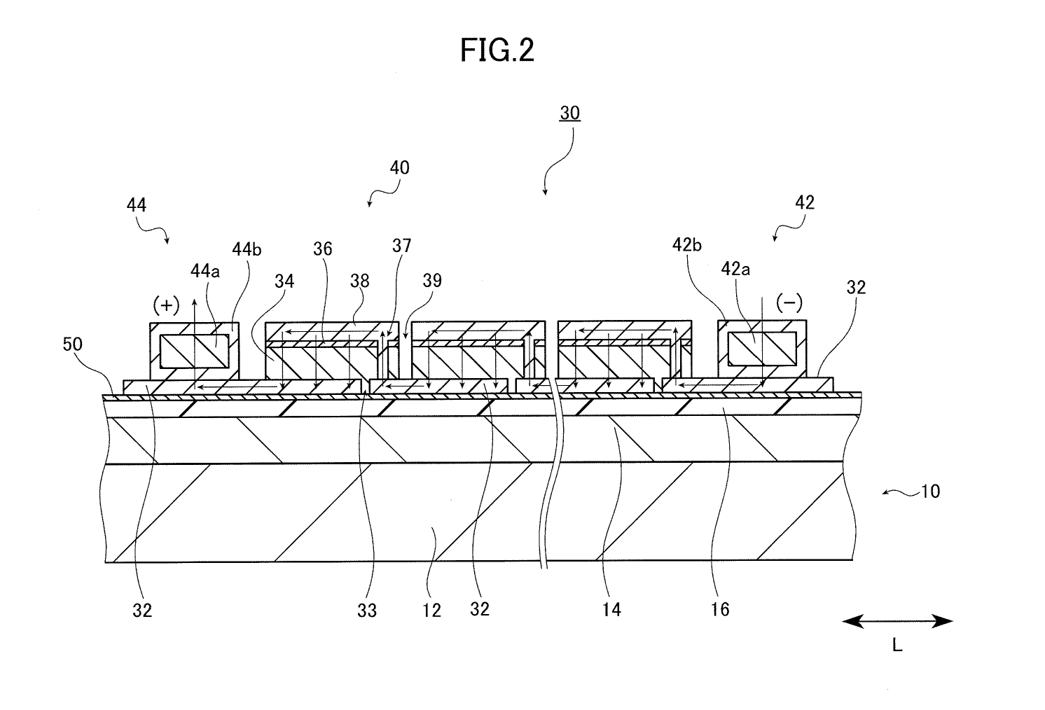

FIG. 1A is a cross-sectional view schematically showing conceptually an example of a substrate for a solar cell of the embodiment of the invention, and FIG. 2 is cross-sectional view schematically showing conceptually an example of the solar cell of the invention.

As shown in FIG. 2, a solar cell 30 of the invention is of a module type in which thin-film solar cells 40 including back electrodes 32, a light absorbing layer 34, a buffer layer 36, and upper electrodes 38 are joined in series on a substrate 10.

As shown in FIG. 1A, the substrate 10 in the solar cell 30 of the invention includes a base 12, an aluminum (Al) layer 14, and an insulation layer 16.

The base 12 and the Al layer 14 are integrally formed. In addition, the insulation layer 16 is made of an anodized aluminum film of an Al porous structure obtained by anodizing the surface of the Al layer 14. Note that the laminated and unified form of the base 12 and the Al layer 14 is referred to as a metallic substrate 15.

In the solar cell 30 of the invention, a ferritic stainless steel is used for the (metallic) base 12 making up the substrate 10.

The invention having such a structure can suppress cracking and delamination of the insulation layer 16 made of the anodized aluminum film and partial peeling of the light absorbing layer 34 in the shape of spots even if the light absorbing layer 34 to be described later is formed at a high temperature of 500 deg C. or more.

As also described in Non-Patent Literature 1, cracks are occurred in the anodized film formed at the aluminum surface by heating to a temperature of 120 deg C. or more.

This is presumably because the linear thermal expansion coefficient (coefficient of linear thermal expansion) is different between the Al layer and the anodized film, that is, aluminum has a larger linear thermal expansion coefficient (23 ppm/K) than the anodized film.

That is, upon measurement of the linear thermal expansion coefficient of the anodized aluminum film, the inventors found the value to be 5 ppm/K. In view of this point, the anodized film cannot withstand the stress caused by the large difference in the linear thermal expansion coefficient of about 18 ppm/K and therefore cracks are considered to be formed in the anodized film on the aluminum material as described above.

Therefore, in a solar cell using the substrate 10 having an insulation layer 16 obtained by anodizing the surface of an Al layer 14, heating may cause cracking or delamination of the insulation layer during the formation of a light absorbing layer made of a compound semiconductor which requires a film deposition temperature of 500 deg C. or more, whereupon sufficient insulation properties cannot be obtained.

In contrast, according to the invention which includes the base 12 made of a ferritic stainless steel having a coefficient of linear thermal expansion close to that of aluminum oxide, the Al layer 14 formed on a surface of the base 12, and the insulation layer 16 made of the anodized aluminum film the stress state of which at room temperature is compressive stress and that is formed on a surface of the Al layer 14, cracking of the insulation layer 16, that is, the anodized aluminum film due to the difference in the linear thermal expansion coefficient can be suppressed.

In addition, the ferritic stainless steel has a linear thermal expansion coefficient of about 10 ppm/K, which is close to that of the light absorbing layer 34 made of CIGS. Therefore, delamination of the light absorbing layer 34 that may occur in the cooling step following the formation of the light absorbing layer 34 at high temperatures can also be suppressed.

In addition, although depending on the degree of mechanical processing and thermal refining, aluminum has a proof stress at room temperature of at least 300 MPa but the proof stress lowers at 500 deg C. to not more than 1/20 that at room temperature. On the other hand, the proof stress of the ferritic stainless steel at 500 deg C. is kept at a level of about 70% of that at room temperature. Therefore, the base 12 made of the ferritic stainless steel dominates the elastic stress limit at high temperatures and thermal expansion of the substrate 10.

In other words, sufficient rigidity of the substrate 10 can be ensured even in an environment of a high temperature of 500 deg C. or more by forming the substrate 10 including not only the Al layer 14 but also the base 12 made of the ferritic stainless steel. Even in cases where the process contains a manufacturing step at a high temperature of 500 deg C. or more, sufficient rigidity of the substrate 10 can be ensured, thus enabling limitations to handling during the manufacture to be eliminated.

In addition to the ferritic stainless steels, it is also possible to use austenitic stainless steels, iron, and carbon steels for the base which prevents cracking of the insulation layer 16 due to the difference in the linear thermal expansion coefficient between the Al layer and the insulation layer 16 made of the anodized aluminum film.

However, in the case of using the austenitic stainless steels for the base 12, cracking of the insulation layer 16 cannot be fully suppressed particularly upon formation of the light absorbing layer 34 at a film deposition temperature exceeding 550 deg C. because of the difference in the linear thermal expansion coefficient. In addition, in the case of using the austenitic stainless steels for the base, the light absorbing layer 34 and particularly the light absorbing layer 34 made of CIGS may occurred partially peeling off in the shape of spots.

On the other hand, iron and the carbon steels have a linear thermal expansion coefficient of about 12 ppm/K, which is close to that of CIGS as in the ferritic stainless steels.

Nevertheless, the substrate 10 in which the Al layer 14 is formed on the surface of the base 12 made of these metallic sheets forms a thick intermetallic compound at the interface between the Al layer 14 and the base 12 when the temperature exceeds 500 deg C. As a result, cracks are easily formed at the interface between the Al layer 14 and the base 12, which lowers the strength at the interface between the aluminum and the metal. The formation of the intermetallic compounds causes the Al layer 14 to be corroded and reduce its thickness excessively, which may locally bring the intermetallic compounds into direct contact with the insulation layer 16 (anodized film). The function of the stress relaxation of the Al layer 14 cannot be expected and it is also highly possible for the contact portions to serve as the starting points for cracking of the insulation layer 16.

These points will be described later in the Embodiments.

In the practice of the invention, the ferritic stainless steel for use in the base 12 is a Fe—Cr stainless steel having the same crystal structure as iron. Illustrative examples of the ferritic stainless steel that may be used include JIS SUS400 series alloy steels such as SUS430, SUS405, SUS410, SUS436, SUS444, and SUS447J1. Further, Mn, Mo, Al, Ti, Si, and Cu may be added as necessary, and the ferritic stainless steels that inevitably include C, N, P, and S may also be used.

The thickness of the base 12 is also not particularly limited but is preferably from 10 to 1000 micrometers in terms of the balance between the flexibility and the strength (rigidity) and the handleability.

While the strength of the base 12 is not particularly limited, the ferritic stainless steels have a strength of 250 to 900 MPa at room temperature given a proof stress of 0.2%, and maintain a room temperature strength of about 70% even at the high temperature of 600 deg C. With this arrangement, it is possible to ensure that the elastic limit stress is not reached, eliminating plastic deformation even in a case where the substrate 10 experiences a heat history of 500 deg C. or more, which is the temperature for formation of the light absorbing layer, and undergoes tensile stress during manufacturing by a roll-to-roll process.

The 0.2% proof stress of the ferritic stainless steels tends to increase proportionately with increases in Cr. Note that each of the ferritic stainless steels has sufficient strength for continual manufacture using a roll-to-roll process.

The 0.2% proof stress is described in “Steel Material Handbook” edited by the Japan Institute of Metals and the Iron and Steel Institute of Japan, published by Maruzen Co., Ltd. or in “Stainless Steel Handbook (3rd edition),” edited by the Japan Stainless Steel Association and published by the Nikkan Kogyo Shimbun, Ltd.

The Al layer 14 is formed on a surface of the base 12.

The Al layer 14 is an aluminum-based layer and various materials such as aluminum and aluminum alloys may be used. More specifically, aluminum with a purity of at least 99 mass % which contains few impurities is preferably used. For example, 99.99 mass % Al, 99.96 mass % Al, 99.9 mass % Al, 99.85 mass % Al, 99.7 mass % Al, and 99.5 mass % Al are preferred.

Aluminum for industrial use may also be used even if it is not high-purity aluminum. Use of such aluminum for industrial use is advantageous in terms of cost. However, it is important for silicon not to deposit in aluminum in terms of the insulation properties of the insulation layer 16.

In the substrate 10 of the invention there exists an alloy layer (inter-metallic layer) in the interface between the base 12 and the Al layer 14, although this layer is not shown in FIG. 1. This alloy layer is made of Al, Fe serving as the main component of ferritic stainless steel, and Cr, and is primarily a layer made of inter metallic compounds (IMC). Specifically, the alloy layer has a composition approximate to Al₃ (Fe.Cr), and the Fe and Cr ratio is close to that of the ferritic stainless steel used.

In the invention, the thickness of the alloy layer (inter-metallic layer) refers to the average thickness of the cross-section of the substrate 10. The average thickness of the cross-section of the substrate 10 may be measured by observation thereof. Specifically, the thickness of the alloy layer is found by cutting the substrate 10 (solar cell 30) to obtain a cross-section thereof, taking an image of this cross-section using an SEM (scanning electron microscope), measuring the surface area of the alloy layer in the image by image analysis, and dividing that surface area by the length of the observed view.

In addition, when the alloy layer is thin, the alloy layer is formed in the shape of individual islands in the interface between the base 12 and the Al layer 14 when the alloy layer is thin. At this time as well, the thickness of the alloy layer may be regarded as the average thickness as described above rather than the thickness of each island.

The alloy layer does not have a uniform thickness, but is rather somewhat uneven. Nevertheless, while recognized as somewhat uneven, the alloy layer usually grows substantially uniformly without any abnormal growth such as a growth that largely grows into the base 12 and the Al layer 14, such as a faceted growth or whisker growth. Therefore, the thickness of the alloy layer can be accurately measured using a method that employs an image such as described above.

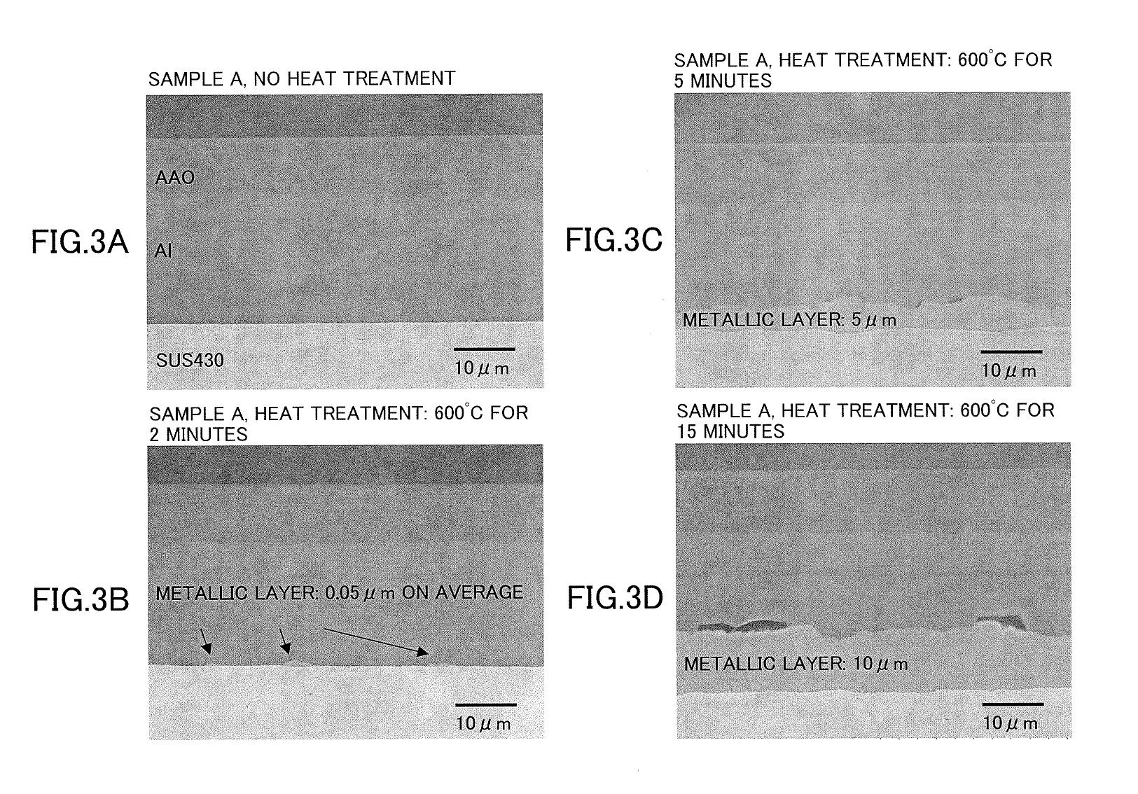

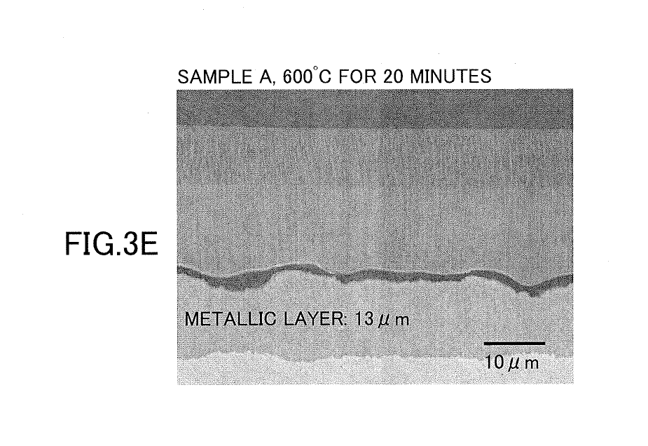

FIGS. 3A to 3E are enlarged views of an alloy layer section formed by joining a commercially available ferritic stainless steel (SUS430) and a commercially available high-purity Al (purity: 4N) using a cold rolling technique and then subjecting the resultant dual-layer clad material having a 30 micrometers thick Al layer 14 and a 50 micrometers thick base 12 (stainless steel) to various heat treatments. FIG. 3A shows a sample (alloy layer (inter-metallic layer): 0 micrometers) not subjected to heat treatment, FIG. 3B shows a sample (alloy layer (inter-metallic layer): 0.05 micrometers) heat-treated for 2 minutes at 600 deg C., and FIG. 3C shows a sample (alloy layer (inter-metallic layer): 5 micrometers) heat-treated for 5 minutes at 600 deg C., FIG. 3D shows a sample (alloy layer (inter-metallic layer): 10 micrometers) heat-treated for 15 minutes at 600 deg C., and FIG. 3E shows a sample (alloy layer (inter-metallic layer): 13 micrometers) heat-treated for 20 minutes at 600 deg C.

As shown in FIG. 3A, sample A, which was not heat-treated, was not found to have an alloy layer under SEM observation up to a magnification of 10,000.

Conversely, all examples in which the sample was retained at high temperatures formed an alloy layer at the interface between the base 12 (SUS430 steel) and the Al layer 14. When the heat treatment time was short or when the temperature was not very high, the alloy layer was formed in shapes of islands about 1 micrometers thick, maximum, as shown in FIG. 3B, resulting in the aforementioned average thickness of 0.05 micrometers. On the other hand, in samples that were heat-treated at a higher temperature or for a longer period of time, the average thickness was at least 1 micrometers and the sample grew to form a continuous layer, as shown in the other figures. While recognized as uneven on the Al layer 14 side, the alloy layer grew substantially uniformly and was not recognized as having any abnormal growths that largely grew into the Al side.

In addition, an alloy layer EDX (energy dispersive X-ray spectroscope) analysis was conducted and the molar composition of the alloy layer was estimated to be Al:Fe:Cr=3:0.8:0.2. The alloy layer is assumed to be layer in which a Cr has gone into solid solution at the Fe site of Al₃Fe composition of the intermetallic compound. Note that the MOL ratio Fe:Cr=8:2 substantially matches the MOL ratio in SUS430.

When the thickness of the alloy layer was about 5 micrometers, a void presumed as a Kirkendhal Void was found at the interface between the alloy layer and the Al layer 14, as shown in FIG. 3C.

In addition, an alloy layer thickness of about 10 micrometers was found to increase the voids and result in a section having a crack that combined the voids, as shown in FIG. 3D. Nevertheless, the length of the crack stopped increasing at a maximum of 10 micrometers, and the crack area observed at low magnification was observed to be most ¼ of the observed view.

Furthermore, those samples with an alloy layer thickness exceeding 10 micrometers upon growth showed a crack across the entire interface of the observed view, as shown in FIG. 3E.

Even with an alloy layer thickness of 10 micrometers, the sample was recognized as substantially free of leak current abnormalities and assessed as applicable, as indicated in the examples described later. Nevertheless, the crack-shaped void at the interface is possibly not advantageous from the viewpoint of long-term reliability. For this reason, in the present invention, the preferred thickness of the alloy layer is 5 micrometers or less.

On the other hand, when the alloy layer is completely non-existent in the substrate 10, the interface adhesion between the base 12 and the Al layer 14 is poor, resulting in the fear that delamination will occur at the interface between the base 12 and the Al layer 14 when a heat cycle or bending strain is applied during the manufacturing process using the roll-to-roll process or during use of the solar cell 30, and that delamination or cracking of the insulation layer 16 will occur based on the interface delamination. Thus, the alloy layer preferably has a thickness of 0.01 to 10 micrometers, and more preferably 0.01 to 5 micrometers.

An alloy layer thickness of 0.01 to 10 micrometers makes it possible to favorably maintain the interface adhesion between the base 12 and the Al layer 14, favorably keep the insulation properties of a substrate 10b even when a void or voids induced by the alloy layer occurs, and favorably suppress curling and interface delamination. In particular, an alloy layer thickness of 0.01 to 5 micrometers makes it possible to more favorably suppress the production of voids, and more reliably suppress curling and interface delamination as well as decreases in insulation performance caused by these.

Note that, when the alloy layer is thin, it is often produced in the shape of individual islands at the interface between the base 12 and the Al layer 14. Even with an alloy layer having such island shapes, the effect of the alloy layer is favorably achieved.

Exemplary methods of alloy layer formation include forming the Al layer 14 on a surface of the base 12 to obtain the metallic substrate 15, and then heat-treating the metallic substrate 15. Or, preparing a composite material having the base 12, the Al layer 14, and the insulation layer 16, such as shown in FIG. 1A, and then heat-treating the material. Thus, in a case where the insulation layer 16 is to be imparted with compressive stress by the aforementioned heat treatment, the alloy layer can be simultaneously formed.

Further, in a case where a certain level of adhesion is maintained between the base 12 and the Al layer 14 of the composite material, a high temperature step of forming the light absorbing layer 34 described later can simultaneously serve as an alloy layer formation step in place of (or in addition to) formation of the alloy layer by heat treatment of the composite material described above.

In the step of manufacturing the solar cell 30, the rule of addition (additivity rule) holds true when the substrate 10 experiences high temperatures multiple times. For example, the alloy layer thickness can be reduced to 10 micrometers (5 micrometers) or less by adding the temperatures and times of each heat treatment, such as annealing, making it possible to change the insulation layer 16 to a state of compressive stress.

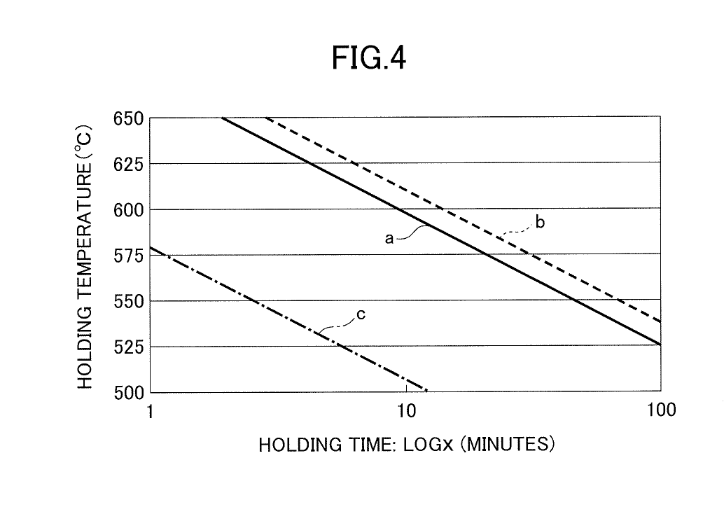

The reactivity with Al is increasingly suppressed in proportion to the amount of Cr of the ferritic stainless steel. FIG. 4 shows examples of the temperature and time for achieving a 10 micrometers thick reactive layer with Al using a mild steel (equivalent to SPCC), SUS430 (Cr steel: 17 mass %), and SUS447J1 (Cr steel: 30 mass %). Given the same heat history, SUS447J1 having a higher Cr content has a lower reactivity and is thus preferred. This also relates to preferred conditions when forming the compound of the light absorbing layer 34.

Note that, in FIG. 4, a represents SUS430 (Cr steel: 17 mass %), b represents SUS447J1 (Cr steel: 30 mass %), and c represents mild steel (equivalent to SPCC).

Given temperature Y (deg C) and time x (minutes), the heat history for obtaining an alloy layer having a thickness of 10 micrometers is Y=670-72.5 Log x and Y=683-72.5 Log x for SUS430 and SUS447J1, respectively.

While the alloy layer thickness needs to be 10 micrometers or less even when forming the compound of the light absorbing layer 34 at a temperature of 500 deg C. or more, use of SUS447J1 for the base 12 makes it possible to form the layer at a substrate temperature that is a little over 10 deg C. higher than a case where SUS430 is used given the same deposition time.

On the other hand, when mild steel is used for the base 12, the holding time needs to be kept within a few minutes to obtain an alloy layer of 10 micrometers or less at 500 deg C. or more, making it substantially difficult to form the compound of the light absorbing layer 34.

The thickness of the Al layer 14 is not particularly limited and may be appropriately selected, but is preferably at least 0.1 micrometers and less than or equal to the thickness of the base 12 made of the ferritic stainless steel, in the state of the solar cell 30.

The thickness of the Al layer 14 is reduced by the pretreatment of the aluminum surface, the formation of the insulation layer 16 by anodization, and the formation of intermetallic compounds at the interface between the Al layer 14 and the base 12 (made of the ferritic stainless steel) during the deposition of the light absorbing layer 34. Therefore, it is important for the thickness of the Al layer 14 in its formation to be described later to be determined in consideration of the reduction of the thickness due to the foregoing factors so that the Al layer 14 may remain between the base 12 and the insulation layer 16 in the state of the solar cell 30.

The insulation layer 16 is formed on the Al layer 14 (on the opposite side from the base 12). The insulation layer 16 is made of an anodized aluminum film obtained by anodizing the surface of the Al layer 14.

Various types of film obtained by anodizing aluminum may be used for the insulation layer 16 but a porous anodized film having compressive stress at room temperature and obtained from an acidic electrolytic solution to be described later is preferably used. The anodized film is an alumina oxide film having micropores with a size of several tens of nm, and has a low Young's modulus and therefore exhibits a high flexural capacity and a high resistance to cracking that may be caused by the difference in the thermal expansion at high temperatures. Furthermore, since the internal stress is compressive stress, it is possible to make a solar cell that suppresses time degradation and exhibits stable performance over a long period of time, even in a case where the solar cell is subjected to repeated bending deformation and thermal strain cycles.

The compressive stress of the anodized aluminum film layer that constitutes the insulation layer 16 is 4 to 400 MPa, preferably 10 to 300 MPa, and more preferably 50 to 200 MPa. When the stress is tensile stress, the flexural capacity is poor and cracks readily occur due to the high temperature heat history.

When the compressive stress is excessive, the stress approaches the compressive fracture stress of the anodized aluminum film constituting the insulation layer 16, possibly deteriorating its repeated bending durability and durability over time.

The internal stress “s” is found by multiplying the difference between the length under restricted conditions and the length under non-restricted conditions (dL) by the Young's modulus of the anodized film.

In the invention, the length of the anodized film is first measured in the state of the substrate 10.

Next, the metallic substrate 15 is dissolved and removed, and the anodized film is taken from the substrate 10. Subsequently, the length of the anodized film is measured. dL is found from this length after removal of the metallic substrate 15.

When the length of the anodized film is longer after removal of the metallic substrate 15, the stress of the anodized film becomes compressive stress; and when the length of the anodized film is shorter after removal of the metallic substrate 15, the stress of the anodized film becomes tensile stress.

On the other hand, the Young's modulus of the anodized film can be found by conducting an indentation test or a push-in test using an indentation testing machine or a nanoindenter on the anodized film in the state of the substrate 10 as is.

In addition, the Young's modulus of the anodized film can be found by removing the metallic substrate 15 from the substrate 10, removing the anodized film, and then conducting the indentation test on the removed anodized film using the indentation testing machine or the nanoindenter.

Further, the Young's modulus of the anodized film can be found by conducting a tensile test on or measuring the dynamic viscoelasticity of either a sample in which a thin metallic film such as aluminum was formed on the anodized film or an anodized film singly removed from the substrate 10.

Note that measuring the Young's modulus of a thin film using the indentation test may adversely affect the metallic substrate 15, and thus the indentation depth generally needs to be suppressed to within about one-third of the thickness of the thin film. For this reason, to accurately measure the Young's modulus of the anodized film having a thickness of about 10 micrometers, measurement using a nanoindenter which is capable of measuring Young's modulus even with an indentation depth of a few hundred nm is preferred.

Note that the length of the anodized film before and after removal of the metallic substrate 15 may be the length of the entire anodized film or the length of a portion of the anodized film.

In a case where the metallic substrate 15 is dissolved, the solution employed may be a copper chloride hydrochloric acid aqueous solution, a mercury chloride hydrochloric acid aqueous solution, a tin chloride hydrochloric acid aqueous solution, or an iodine methanol solution. The solution for dissolving is appropriately selected in accordance with the composition of the metallic substrate 15.

In the invention, in addition to removal of the metallic substrate 15, the warpage and deflection of the metallic base having a high planarity, for example, are measured, an anodized film is formed on only one side of the metallic base, and then the warpage and deflection of the metallic base after formation of the anodized film are measured. The warpage and deflection values before and after formation of the anodized film are then converted to stress values.

The warpage and deflection of the metallic base are measured using, for example, an optically precise measurement method employing a laser. Specifically, the various measurement methods described in the “Journal of the Surface Finishing Society of Japan,” 58, 213 (2007), and in “R&D Review of Toyota CRDL’ 34, 19 (1999) may be used to measure the warpage and deflection of the metallic base.

Note that, since all methods other than the method in which the metallic substrate 15 is removed measure the strain of the anodized film with the metallic substrate 15 remaining as is, it is difficult to say that such methods completely remove the restrictions on the metallic substrate 15. In addition, while the metallic substrate 15 is a composite material of Al and ferritic stainless steel and the Young's modulus of Al is presumably low, the internal stress of the anodized film is an approximation. If the method used is one in which the metallic substrate 15 is removed, the strain of the anodized film itself can be directly measured without any restraint on the metallic substrate 15. For this reason, the stress value in the invention is found by multiplying the difference between the lengths before and after removal of the metallic substrate 15 by the Young's modulus found from the indentation test.

The insulation layer 16 preferably has a thickness of at least 2 micrometers and more preferably at least 5 micrometers. An excessively large thickness of the insulation layer 16 reduces its flexibility and increases the cost and time required for formation thereof, and is thus not preferred. In practice, the thickness of the insulation layer 16 is 50 micrometers, maximum, and preferably 30 micrometers, maximum. Therefore, the preferred thickness of the insulation layer 16 is from 2 to 50 micrometers.

A surface 18a of the insulation layer 16 has a surface roughness in terms of, for example, arithmetic mean roughness Ra is 1 micrometers or less, preferably 0.5 micrometers or less, and more preferably 0.1 micrometers or less.

The substrate 10 includes the base 12, the Al layer 14 and the insulation layer 16 which are all made of flexible materials, and is therefore flexible as a whole. An alkali supply layer, the back electrodes, the light absorbing layer and the upper electrodes can be thus formed on the insulation layer 16 side of the substrate 10 by, for example, a roll-to-roll process.

In the practice of the invention, a plurality of films may be formed in the process from the feed of the substrate from the roll to the take-up thereof to prepare a solar cell structure, or the process including the feed of the substrate from the roll, film deposition and take-up of the substrate may be performed a plurality of times to prepare a solar cell structure. As will be described later, a scribing step for separating and integrating elements may be added between the respective film deposition steps in the roll-to-roll process to prepare a solar cell structure in which a plurality of solar cells are electrically connected in series.

The invention is not limited to the case in which the Al layer 14 and the insulation layer 16 are formed only on one surface of the base 12, and the substrate used for the solar cell of the invention may be the one having the Al layer 14 and optionally insulation layer 16 on both surfaces of the base 12.

In other words, the composite structure of the substrate may not be a bimetal structure of a (ferritic stainless) steel and aluminum.

There is no problem even if the substrate is of a structure of Al layer 14/base 12/Al layer 14 for example in terms of preventing corrosion of the steel used. The substrate 10 may be curled by thermal strain during the formation of the light absorbing layer 34 at high temperatures. In such a case, the substrate 10 may be of a five-layer structure that structure of insulation layer 16a/an Al layer 14a/base (steel) 12/Al layer 14b/insulation layer 16b as schematically shown in FIG. 1B. In such a case, the metallic substrate 15 is formed by the Al layer 14a, the base 12, and the Al layer 14b.

The method of manufacturing the substrate 10 is described below.

The base 12 is first prepared. The base 12 formed has predetermined shape and size suitable to the size of the substrate 10 to be formed.

Then, the Al layer 14 is formed on a surface of the base 12 to obtain the metallic substrate 15.

Known methods of integrating Al material into the base to form a metallic substrate include hot-dip plating of the base. Nevertheless, since the melting point of aluminum is 660 deg C., the hot-dip plating temperature generally needs to be 700 deg C. or more. The inventors have confirmed that a metallic substrate that has experienced such high temperatures produces voids and cracks in association with an alloy layer having a thickness exceeding 10 micrometers and formation thereof at the interface between the base 12 and the Al layer 14 of the ferritic stainless steel. In such a case, when bending strain is applied to the substrate as described above, delamination occurs at that interface, resulting in failure to achieve a flexible solar cell.

In addition, known molten aluminum coated steel sheets include Galvalume steel sheets. Adding a little more than 40 mass % of zinc and a few mass % of silicon to aluminum thus decreases the melting temperature and controls formation of an alloy layer made of a base material and aluminum alloy material at the interface between the base and the aluminum material (here, an aluminum alloy material made of aluminum, zinc, and silicon). Use of an aluminum alloy material with this technique reduces the melting point, making it possible to control the formation of the alloy layer with the base at the interface. Nevertheless, to decrease the melting temperature of the aluminum alloy material from 660 deg C. by 100 deg C. or more, the addition of an alloy element of 10 mass % or more is generally required. The inventors have confirmed that the anodized film obtained by anodizing an aluminum alloy plated layer made of an aluminum alloy material that includes an alloy element in an amount of 10 mass % or more in aluminum cannot satisfy insulation performance in terms of the high withstand voltage and low insulation leak current required for a solar cell of a module structure.

On the other hand, with the metallic substrate 15 in which the base 12 and the Al layer 14 have been unified by pressurizing and bonding, an alloy layer is virtually not produced at the interface between the base 12 and the Al layer 14 as long as the two are bonded without adding heat when pressurized and bonded.

In addition to the aforementioned hot-dip plating, other possible methods used to form the metallic substrate include, for example, vapor phase methods such as Al vapor deposition or sputtering on the base, and electrical aluminum plating that uses a non-aqueous electrolytic solution. Nevertheless, it is difficult to prepare a large-area metallic substrate using a standard device employed with such methods, and thus attempts to prepare a large-area metallic substrate result in extremely high costs. A metallic substrate in which the Al material is unified with the base by a vapor phase method or electrical aluminum plating is therefore impractical and not at all suited for a substrate of a solar cell of a module structure having a large area and capable of power system linkage.

Thus, from the viewpoint of ease of large-area substrate preparation, low cost, and high mass productivity, the bonding of the base 12 and the Al layer 14 is ideally achieved by pressure bonding by rolling, etc. In particular, the base 12 and the Al layer 14 are preferably bonded by pressure without heating. In other words, the base 12 and the Al layer 14 are bonded under ambient temperature without the external addition of heat.

Next, the method of forming the anodized film serving as the insulation layer 16 is described.

The anodization treatment can be performed using, for example, a known anodizing device of a so-called roll-to-roll process.

The anodized film serving as the insulation layer 16 can be formed by immersing the base 12 serving as the anode in an electrolytic solution together with the cathode and applying voltage between the anode and the cathode. The base 12 forms a local cell with the Al layer 14 upon contact with the electrolytic solution and therefore the base 12 contacting the electrolytic solution is to be masked and isolated using a masking film (not shown). That is, the end surfaces and the back surface of the metallic substrate 15 other than the surface of the Al layer 14 need to be insulated using masking film (not shown). Note that the method of masking during the anodization treatment is not limited to the use of masking film. Possible masking methods include, for example, a method in which the end surfaces and the back surface of the metallic substrate 15 other than the surface of the Al layer 14 are protected using a jig, a method in which water-tightness is ensured using rubber, and a method in which the surfaces are protected using resist material.

Where necessary, pre-anodization may include steps of subjecting the surface of the Al layer 14 to cleaning and polishing processes.

Exemplary electrolytic solutions used for anodization include an aqueous electrolytic solution such as an inorganic acid, organic acid, alkali, buffer solution, or combination thereof, and non-aqueous electrolytic solutions such as an organic solvent or molten salt. Specifically, an anodized film can be formed on the surface of the Al layer 14 by introducing direct current or alternating current to the Al layer 14 in an aqueous solution or non-aqueous solution of an acidic solution of sulfuric acid, oxalic acid, chromic acid, formic acid, phosphoric acid, malonic acid, diglycolic acid, maleic acid, citraconic acid, acetylenedicarboxylic acid, malic acid, tartaric acid, citric acid, glyoxalic acid, phthalic acid, trimellitic acid, pyromellitic acid, sulfamic acid, benzene sulfonic acid, or amide sulfonic acid, or a combination of two or more thereof. Carbon or aluminum is used for the cathode during anodization.

An oxidation reaction proceeds substantially in the vertical direction from the surface of each of the Al layer 14 to form the anodized film at the surface of each of the Al layer 14 when the anodization treatment is performed in such an acidic solution. At this time, the anodized film is of a porous type in which a large number of fine columns in the shape of a substantially regular hexagon as seen from above are densely arranged, and a micropore having a rounded bottom is formed at the core of each fine column, the bottom of each fine column having a barrier layer with a thickness of typically 0.02 micrometers to 0.1 micrometers.

The anodized film having such a porous structure has a low Young's modulus compared to a simple aluminum oxide film of a non-porous structure. Therefore, High crack resistance due to its thermal expansion difference at high temperatures, and flexural capacity is good. After the porous anodized film is formed in the acidic electrolytic solution, an anodized film that increases the thickness of the barrier layer may be formed by a pore filling method that subjects the film to electrolytic treatment once again in a neutral electrolytic solution. The film can have higher insulation properties by increasing the thickness of the barrier layer.

The anodized film of a thickness of 3 micrometers or more and prepared on the Al layer at room temperature in a typical sulfuric acid bath are known to have tensile stress as described in JP 2002-196603 A.

On the other hand, anodized film prepared in a high-temperature bath of 50 deg C. or more and anodized film heat-treated at a temperature of 100 deg C. or more after formation may be imparted with compressive stress at room temperature, regardless of thickness.

The former is understood to have compressive stress due to the difference in thermal expansion of the metallic substrate at room temperature and at the temperature of formation of the anodized film. As previously described, the linear thermal expansion coefficient of Al is 23 ppm/K, the linear thermal expansion coefficient of ferrite stainless steel is 10 ppm/K, and the linear thermal expansion coefficient of anodized film is about 5 ppm/K regardless of the acid type and film thickness during electrolysis, resulting in compression of the anodized film during cooling after formation.

The latter results in stress relaxation with the anodized film in a state of tensile stress due to the difference in thermal expansion with the metallic base 12 when kept at a high temperature, making it possible to impart compressive stress during subsequent cooling.

The anodized film is an oxide film formed in an aqueous solution, and it is known that moisture is retained inside a solid, as described in “Chemistry Letters,” Vol. 34, No. 9, (205), p. 1286 (hereinafter, “Literature 1”), for example.

From the same solid NMR measurements of the anodized film as in Literature 1, it is understood that the moisture content (OH group) inside the solid body of the anodized film decreases when the film is heat-treated at 100 deg C. or more. Thus, heating changes the bound state of Al—O and Al—OH, presumably resulting in stress relaxation (an annealing effect).

The decrease in moisture content (OH group) becomes saturated in 1 to 60 minutes, depending on the heat treatment temperature. Therefore, stress relaxation is presumed to proceed, requiring about that much time. Once moisture elimination within the solid body becomes saturated and the Al—O bound state no longer changes, stress relaxation no longer occurs, and the stress state changes to compressive stress at room temperature due to the difference in thermal expansion with the metallic base during cooling.

The Young's modulus of each member of the substrate 10 is 200 and 70 GPa at room temperature for the base 12 and the Al layer 14, respectively, and 50 to 130 GPa for the porous anodized film, depending on the porous structure. The thermal expansion properties of the substrate 10 is dominated by the properties of the base 12 having a high Young's modulus and high thickness.

Thus, when the film is anodized at a temperature higher than room temperature, the film exhibits compressive stress at room temperature due to the difference in thermal expansion from the base 12 when cooled, even if the film exhibits zero internal stress or tensile stress in the state of deposition. Further, when heat-treated at a high temperature after formation, the anodized film in a state of tensile stress is subjected to stress relaxation due to the dehydration annealing effect, causing the internal stress to change to compressive stress at room temperature due to the difference in thermal expansion from the base 12.

When the anodization treatment is performed at a temperature higher than room temperature as described above, the temperature is preferably 50 deg C. or more, and the electrolytic solution used preferably includes an acid having a pKa (acid dissociation constant) at 25 deg C. of 2.5 to 3.5.

Note that the electrolytic solution used for anodization treatment has a boiling point of 100 deg C+elevation, but performing the anodization treatment at the boiling point of the aqueous solution is not practical and byproducts (boehmite) are produced to the extent the temperature is high. Thus, the upper limit of the temperature of the aqueous solution is 98 deg C., which is lower than the boiling point, and more preferably 95 deg C. or less.

The reason that the preferred pKa at 25 deg C. is at least 2.5 can be explained by the relationship between the anodized film and the rate of dissolution by the acid. The pKa, that is, the strength of the acid is known to be somewhat correlated with the dissolution speed of the anodized film [as described in the Journal of the Surface Finishing Society of Japan, 20, 506, (1969), for example]. The actual growth of the anodized film is a complex reaction that proceeds as generation of the anodized film by an electrochemical reaction and dissolution of the anodized film by acid simultaneously occur, making the rate of dissolution of the anodized film a primary cause of film formation.

When the pKa is less than 2.5, the rate of dissolution at a high temperature is too high compared to the generation of the anodized film, sometimes causing failure to achieve stable growth of the anodized film and formation of a relatively thin film that reaches the critical film thickness, resulting in an inadequate anodized film serving as the insulation layer.

On the other hand, the pKa at 25 deg C. is preferably 3.5 or less, and more preferably 3.0 or less. When the pKa at 25 deg C. exceeds 3.5, the rate of dissolution is too slow even at a high temperature compared to the generation of the anodized film, sometimes causing formation of the anodized film to be extremely time consuming and failure to form a thick anodized film by forming an anodized film so called barrier type, resulting in an inadequate anodized film serving as the insulation layer.

Exemplary acids having a pKa (acid dissociation constant) of 2.5 to 3.5 include, for example, malonic acid (2.60), diglycol acid (3.0), malic acid (3.23), tartaric acid (2.87), citric acid (2.90), glyoxalic acid (2.98), phthalic acid (2.75), and trimellitic acid (2.5). The solution used for anodization may be a mixed solution of such acids having a pKa (acid dissociation constant) of 2.5 to 3.5, other acids, bases, salts, and additives.

In the embodiment under consideration, the metallic substrate 15 is subjected to anodization treatment in an aqueous solution including an acid having a pKa (acid dissociation constant) of 2.5 to 3.5 at a temperature of 50 deg C. or more, thereby making it possible to achieve an anodized film having a compressive stress of 4 to 100 MPa at room temperature (23 deg C).

The annealing treatment is preferably performed under conditions of 100 to 600 deg C. and a holding time of 1 second to 10 hours. A predetermined compressive stress can be achieved by changing the annealing conditions. The annealed anodized film that forms the insulation layer 16 has a compressive stress of 4 to 400 MPa.

An annealing heating temperature of less than 100 deg C. fails to substantially achieve a compression effect. On the other hand, an annealing heating temperature that exceeds 600 deg C. may result in cracking of the anodized film due to the difference in linear thermal expansion coefficients between the metallic substrate 15 and the anodized film that forms the insulation layer 16 as well as generation of a thick reactive layer (alloy layer) formed at the aforementioned Al/ferritic stainless steel interface, and is therefore not preferred. When the heating temperature is 450 deg C. or more and the temperature rapidly rises, a high tensile stress occurs on the anodized film before the annealing effect has occurred, making the film susceptible to breakdown such as cracking. Thus, the rise in temperature is 5 deg C./second or less, and preferably 1 deg C./second or less.

The annealing holding time is at least 1 second in order to achieve an annealing effect during the temperature rise as well. On the other hand, even if the annealing holding time exceeds 10 hours, compressive stress becomes saturated at room temperature due to the effects of dehydration and stress relaxation, and thus the upper limit is 10 hours.

Note that the additivity rule has been confirmed to apply to a certain degree to the annealing temperature and the subsequent room temperature compressive stress of the anodized film, at least up to about 450 deg C. This can be explained from the fact that the change in moisture content increases as the annealing temperature increases in the aforementioned NMR measurement.

Annealing may be performed in a vacuum, in inert gas, in the atmosphere, or in an oxygen environment.

When the metallic substrate 15 has a dual-layer structure of the base 12 made of ferritic stainless steel and the Al layer 14, the surface opposite the insulation layer 16 is the base 12, forming a natural oxide film of about 5 nm. When the substrate 10 is heat-treated at 300 deg C. or more in the atmosphere or in an oxygen environment, the surface oxide film of the base 12 becomes a thermally oxidized film of 20 nm or more. If selenium is used during formation of the light absorbing layer of the solar cell, this film functions as an anti-Se corrosion film of the stainless steel, serving as an effective substrate in such solar cells that use selenium during formation of the light absorbing layer.

In addition to the above, other exemplary methods for imparting compressive stress on the anodized film of the insulation layer 16 include imparting tension in tensile direction E (refer to FIG. 1A) or imparting curvature, for example, so that the metallic substrate 15 is within the range of elastic deformation, that is, within 0.2% strain, thereby extending the metallic substrate 15 further than its state of usage at room temperature, forming an anodized film in this state, and then releasing the extended state of the metallic substrate 15.

Note that the anodized film having an internal stress that is compressive stress may be manufactured using just one type of method described above, or a combination thereof.

Further, with the temperature rising to 500 deg C. or more during formation of the light absorbing layer 34 (CIGS layer), any method is acceptable as long as compressive stress is produced on the insulation layer 16 during this temperature rise. For example, even with a porous anodized film of tensile stress in a typical acidic electrolytic solution, once a state of slight compressive stress that makes it possible for the substrate to endure the transporting step at room temperature in the roll-to-roll process during annealing at 200 deg C. or less, the temperature may be gradually increased to the formation temperature of the light absorbing layer 34 of 500 deg C. or more to impart the film with high-temperature crack resistance.

In the substrate 10 of the embodiment, the internal stress of the anodized film at room temperature is in a compressive state, making it difficult for cracking to occur and thus achieving excellent cracking resistance.

Moreover, the substrate 10 uses an anodized aluminum film as the insulation layer 16. Since this anodized aluminum film is ceramic, chemical changes do not readily occur at high temperatures, enabling use of the anodized aluminum film as the insulation layer 16 that offers high reliability without cracking. As a result, the substrate 10 is highly resistant to thermal strain and can be used as a preferred heat resistant substrate in a compound solar cell having a process temperature of 500 deg C. or more. In addition, use of the substrate 10 makes it possible to manufacture a thin-film solar cell using a roll-to-roll process, for example, thereby largely improving productivity.

In the substrate 10, the anodized film of the insulation layer 16 is changed to a state of compressive stress at room temperature, making it difficult for cracks to occur even if the film experiences start-to-finish production in a roll-to-roll process process, and imparting the film with resistance to bending strain. When the insulation layer 16 is in a state of tensile stress at room temperature, that is, subjected to tensile strain and a break or crack occurs, that tensile force acts to open up that break or crack, leaving the break or crack in an open state. As a result, the substrate can no longer maintain insulation properties.

Further, since the insulation layer 16 is in a state of compressive stress, damage does not readily occur even if a solar cell that uses the substrate 10 is placed outdoors and subjected to severe temperature changes and external impact. That is, long-term reliability in a state of usage of the solar cell can be achieved.

As described above, the solar cell 30 of the invention shown in FIG. 2 is of a module type (solar cell module) in which the thin-film solar cells 40 composed of the back electrodes 32, the light absorbing layer 34, the buffer layer 36, and the upper electrodes 38 are joined in series on the substrate 10.

The solar cell 30 includes a first conductive member 42 and a second conductive member 44.

In a preferred embodiment shown in FIG. 2, an alkali supply layer 50 (supply source of an alkali metal to the light absorbing layer 34) is formed between the insulation layer 16 (substrate 10) and the back electrodes 32.

It is known for the alkali metal (particularly Na) to have high photoelectric conversion efficiency when diffused into the light absorbing layer 34 made of a material such as CIGS.

The alkali supply layer 50 is a layer for supplying the alkali metal to the light absorbing layer 34 and is a layer of an alkali metal-containing compound. In the practice of the invention, by having the alkali supply layer 50 between the insulation layer 16 and the back electrodes 32, the alkali metal diffuses through the back electrodes 32 into the light absorbing layer 34 during the formation of the light absorbing layer 34, thus enabling the conversion efficiency of the light absorbing layer 34 to be improved.

The alkali supply layer 50 is not particularly limited and various materials consisting primarily of an alkali metal-containing compound (composition containing an alkali metal compound) such as NaO₂, Na₂S, Na₂Se, NaCl, NaF or sodium molybdate may be used. A SiO₂ (silicon oxide)-based compound containing Na₂O (sodium oxide) is particularly preferred.

Note that the SiO₂ and NaO₂ compounds have poor humidity resistance, causing the Na component to separate and readily change to a carbonate. Thus, metallic components with Ca added, namely an oxide having the three components Si—Na—Ca, is more preferred.

The method of forming the alkali supply layer 50 is not particularly limited and various known methods may be used. Exemplary methods include vapor-phase deposition methods such as sputtering and CVD and liquid-phase deposition methods such as a sol-gel method.

For example, given a compound that has the aforementioned SiO₂ as its main component and includes NaO₂, the alkali supply layer 50 may be formed by sputtering using soda-lime glass as the target, sol-gel reaction using an alkoxide that includes Si, Ca, and Na, or dehydration of a sodium silicate aqueous solution that includes Ca. These methods may also be used in combination.

In the practice of the invention, the supply source of the alkali metal to the light absorbing layer 34 is not limited to the alkali supply layer 50.

For example in cases where the insulation layer 16 is made of the porous anodized film, an alkali metal-containing compound may be introduced in the pores of the insulation layer 16 as well so that the insulation layer 16 and the alkali supply layer 50 serve as the supply source of the alkali metal to the light absorbing layer 34. Alternatively, the alkali supply layer 50 is not particularly formed but the alkali metal-containing compound is only introduced in the pores of the insulation layer 16 so that the insulation layer 16 may serve as the supply source of the alkali metal to the light absorbing layer 34.

For example, in cases where the alkali supply layer 50 is formed by sputtering, the insulation layer 16 has no alkali metal-containing compound and only the alkali supply layer 50 formed serves as the alkali metal supply source. In cases where the insulation layer 16 is a porous type anodized film and the alkali supply layer 50 is formed by a sol-gel reaction or dehydration of a sodium silicate aqueous solution, the alkali supply layer 50 is formed and the alkali metal-containing compound is introduced in the pores of the insulation layer 16 so that both of the insulation layer 16 and the alkali supply layer 50 may serve as the alkali metal supply sources to the light absorbing layer 34.

The amount of alkali that serves as the alkali metal supply source differs according to the back electrodes, CIGS structure, and formation method, but the amount of Na per substrate unit area is about 2×10⁻⁶ to 20×10⁻⁶ g/cm² when the Mo electrode thickness is 0.5 micrometers and the CIGS thickness is about 2 micrometers. Note that the ideal amount of alkali differs according to the fine structure of the porous type anodized film, and increases as the anodized film pore size decreases and specific surface area increases.

As described above, the solar cell 30 has the series-connected thin-film solar cells 40 composed of the back electrodes 32, the light absorbing layer 34, the buffer layer 36, and the upper electrodes 38, the first conductive member 42 and the second conductive member 44.

The thin-film solar cells 40 are of a known type of a thin film solar cell using a semiconductor compound such as CIGS or CIS for the light absorbing layer 34.

In the solar cell 30, the back electrodes 32 are disposed away from each other at predetermined spaces 33 on the alkali supply layer 50. The light absorbing layer 34 is formed on the back electrodes 32 so as to fill the spaces 33 between the neighboring back electrodes 32. The buffer layer 36 is formed on a surface of the light absorbing layer 34.

The light absorbing layer 34 and the buffer layer 36 are disposed on the back electrodes 32 so as to have predetermined spaces 37 therein. The spaces 33 between the neighboring back electrodes 32 and the spaces 37 in the light absorbing layer 34 (buffer layer 36) are formed at different positions in the direction of arrangement of the thin-film solar cells 40.

The upper electrodes 38 are formed on a surface of the buffer layer 36 so as to fill the spaces 37 in the light absorbing layer 34 (buffer layer 36).

The upper electrodes 38, the buffer layer 36, and the light absorbing layer 34 are disposed so as to have predetermined spaces 39. The spaces 39 are provided at different positions from the spaces between the neighboring back electrodes 32 and the spaces in the light absorbing layer 34 (buffer layer 36).

In the solar cell 30, the respective thin-film solar cells 40 are electrically connected in series in the longitudinal direction of the substrate 10 (in the direction indicated by an arrow L) through the back electrodes 32 and the upper electrodes 38.

The back electrodes 32 are, for example, molybdenum electrodes. The light absorbing layer 34 is made of a semiconductor compound having a photoelectric conversion function and is, for example, a CIGS layer. In addition, the buffer layer 36 is made of, for example, CdS and the upper electrodes 38 are made of, for example, ZnO.

The thin-film solar cells 40 are formed so as to extend in the width direction perpendicular to the longitudinal direction L of the substrate 10. Therefore, the back electrodes 32 also extend in the width direction of the substrate 10.

As shown in FIG. 2, the first conductive member 42 is connected to the rightmost back electrode 32. The first conductive member 42 is provided to collect the output from the negative electrode as will be described onto the outside.

The first conductive member 42 is, for example, a member in the shape of an elongated strip which extends substantially, linearly in the width direction of the substrate 10 and is connected to the rightmost back electrode 32. As shown in FIG. 2, the first conductive member 42 has, for example, a copper ribbon 42a covered with a coating material 42b made of an alloy of indium and copper. The first conductive member 42 is connected to the back electrode 32 by, for example, ultrasonic soldering.

On the other hand, the second conductive member 44 is formed on the leftmost back electrode 32.

The second conductive member 44 is provided to collect the output from a positive electrode to be described later. As in the first conductive member 42, the second conductive member 44 is a member in the shape of an elongated strip which extends substantially linearly in the width direction of the substrate 10 and is connected to the leftmost back electrode 32.

The second conductive member 44 is composed similarly to the first conductive member 42 and has, for example, a copper ribbon 44a covered with a coating material 44b made of an alloy of indium and copper.

The light absorbing layer (photoelectric conversion layer) 34 in the thin-film solar cells 40 of the embodiment under consideration is made of, for example, CIGS and can be manufactured by a known method of manufacturing CIGS solar cells.

In the solar cell 30, light entering the thin-film solar cell 40 from the side of the upper electrode 38 passes through the upper electrode 38 and the buffer layer 36 and causes electromotive force to be generated in the light absorbing layer 34, thus producing a current that flows, for example, from the upper electrode 38 to the back electrode 32. Note that the arrows shown in FIG. 2 indicate the directions of the current, and the direction in which electrons move is opposite to that of current. Therefore in a photoelectric conversion portion 48, the leftmost back electrode 32 in FIG. 2 has a positive polarity (plus polarity) and the rightmost back electrode 32 has a negative polarity (minus polarity).

In the embodiment under consideration, electric power generated in the solar cell 30 can be output from the solar cell 30 through the first conductive member 42 and the second conductive member 44.

Also in this embodiment, the first conductive member 42 has a negative polarity, and the second conductive member 44 has a positive polarity. The polarities of the first conductive member 42 and the second conductive layer 44 may be reversed; their polarities may vary according to the configuration of the thin-film solar cells 40, the configuration of the solar cell 30, and the like.

In the embodiment under consideration, the thin-film solar cells 40 formed are connected in series in the longitudinal direction L of the substrate 10 through the back electrodes 32 and the upper electrodes 38, but this is not the sole case of the invention. For example, the thin-film solar cells 40 may be formed so as to be connected in series in the width direction through the back electrodes 32 and the upper electrodes 38.

The back electrodes 32 and the upper electrodes 38 of the thin-film solar cells 40 are provided to collect the current generated in the light absorbing layer 34. Both the back electrodes 32 and the upper electrodes 38 are made of a conductive material. The upper electrodes 38 must be have translucency.

The back electrodes 32 are made of, for example, molybdenum (Mo), chromium (Cr), or tungsten (W), or a combination thereof. The back electrodes 32 may be of a single-layer structure or a laminated structure such as a dual-layer structure. The back electrodes 32 are preferably made of molybdenum (Mo).

The back electrodes 32 preferably have a thickness of at least 100 nm and more preferably 0.45 to 1.0 micrometers.

The method of forming the back electrodes 32 is not particularly limited, and the back electrodes 32 may be formed by vapor-phase deposition techniques such as electron beam evaporation and sputtering.

The upper electrodes (transparent electrodes) 38 are made of, for example, ZnO doped with Al, B, Ga, Sb, etc., ITO (indium tin oxide), SnO₂, or a combination of two or more thereof. The upper electrodes 38 may be of a single-layer structure or a laminated structure such as a dual-layer structure. The thickness of the upper electrodes 38 is not particularly limited but is preferably from 0.3 to 1 micrometers.

The method of forming the upper electrodes 38 is not particularly limited, and the upper electrodes 38 may be formed by vapor-phase deposition techniques such as electron beam evaporation and sputtering or a coating method.

The buffer layer 36 is provided to protect the light absorbing layer 34 during the formation of the upper electrodes 38 and allows the light having passed through the upper electrodes 38 to enter the light absorbing layer 34.

The buffer layer 36 is made of, for example, CdS, ZnS, ZnO, ZnMgO, or ZnS (O, OH), or a combination thereof.

The buffer layer 36 preferably has a thickness of 0.03 to 0.1 micrometers. The buffer layer 36 is formed by, for example, chemical bath deposition (CBD) method.

The light absorbing layer 34 absorbs light having reached through the upper electrodes 38 and the buffer layer 36 to generate current and has a photoelectric conversion function. According to this embodiment, the light absorbing layer 34 is not particularly limited in structure; the light absorbing layer 34 is made of, for example, at least one compound semiconductor of a chalcopyrite structure. The light absorbing layer 34 may be made of at least one kind of compound semiconductor composed of a group Ib element, a group IIIb element and a group VIb element.

For higher optical absorptance and higher photoelectric conversion efficiency, the light absorbing layer 34 is preferably made of at least one kind of compound semiconductor composed of at least one group Ib element selected from the group consisting of Cu and Ag, at least one group IIIb element selected from the group consisting of Al, Ga, and In, and at least one group VIb element selected from the group consisting of S, Se, and Te. Examples of this compound semiconductor include CuAlS₂, CuGaS₂, CuInS₂, CuAlSe₂, CuGaSe₂, CuInSe₂(CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂(CIGS), Cu(In₁₋ₓAlₓ)Se₂, Cu(In₁₋ₓGaₓ) (S, Se)₂, Ag (In₁₋ₓGaₓ)Se₂, and Ag(In₁₋ₓGaₓ)(S, Se)₂.

The light absorbing layer 34 preferably contains CuInSe₂(CIS) and/or Cu(In,Ga)Se₂(CIGS), which is obtained by solid-dissolving Ga in the former. CIS and CIGS are semiconductors each having a chalcopyrite crystal structure, and reportedly have high optical absorbance and high photoelectric conversion efficiency. Further, CIS and CIGS have less deterioration of the efficiency under exposure to light and exhibit excellent durability.

The light absorbing layer 34 contains impurities for obtaining a desired semiconductor conductivity type. Impurities may be incorporated in the light absorbing layer 34 by diffusion from a neighboring layer and/or positive doping. The light absorbing layer 34 may have concentration distributions for the elements making up the group I-III-IV semiconductor and/or impurities; the light absorbing layer 34 may contain a plurality of layer regions of different semiconductivities such as n-type, p-type, and i-type.

For example, in a CIGS type, the light absorbing layer 34 which has a distribution of the Ga amount in the thickness direction enables the band gap width and carrier mobility to be controlled to achieve design with high photoelectric conversion efficiency.

The light absorbing layer 34 may contain one or more than one semiconductor other than group I-III-IV semiconductors. Examples of the semiconductor other than the group I-III-IV semiconductors include a semiconductor made of a group IVb element such as Si (group IV semiconductor), a semiconductor made of a group IIIb element and a group Vb element (group III-V semiconductor) such as GaAs, and a semiconductor made of a group IIb element and a group VIb element (group II-VI semiconductor) such as CdTe. The light absorbing layer 34 may contain any other component than the semiconductor and impurities used to obtain a desired conductivity type, provided that no detrimental effects are thereby produced on the properties.

The content of the group I-III-IV semiconductor in the light absorbing layer 34 is not particularly limited. The content of the group I-III-IV semiconductor in the light absorbing layer 34 is preferably at least 75 mass %, more preferably at least 95 mass % and most preferably at least 99 mass %.

In the embodiment under consideration, in cases where the light absorbing layer 34 contains at least 75 mass % of a CdTe compound semiconductor as its main component, film deposition at a temperature of 500 deg C. or more yields high photoelectric conversion efficiency, and the base 12 is preferably made of a ferritic stainless steel in terms of the coefficient of thermal expansion and the reactivity with aluminum.

Exemplary known methods of forming the CIGS layer include 1) multi-source co-evaporation method, 2) selenization method, 3) sputtering method, 4) hybrid sputtering method, and 5) mechanochemical processing method.

1) Known multi-source co-evaporation methods include: the three-stage method (J. R. Tuttle et al., Mat. Res. Soc. Symp. Proc., Vol. 426 (1966), p. 143, etc.), a bilayer method (W. E. Devaney et al., IEEE Trans. On Electron Devices, Vol. 37 (1990), p. 428, etc.), and a co-evaporation method by EC group (L. Stolt et al.: Proc. 13^{th} ECPVSEC (1995, Nice), 1451, etc.), each of these having a vapor deposition source for each element Cu, In, Ga, Se to vapor-deposit the film on the substrate while independently controlling each vapor deposition source in a vacuum.

According to the three-phase method, firstly, In, Ga, and Se are simultaneously evaporated under high vacuum at a substrate temperature of 300 deg C., which is then increased to 500 deg C. to 560 deg C. to simultaneously vapor-deposit Cu and Se, whereupon In, Ga, and Se are simultaneously evaporated. According to the bilayer method, the CIGS layer is formed using a method in which the four elements Cu, In, Ga, and Se are evaporated in a first stage, and the three elements In, Ga, and Se, excluding Cu, are vapor-deposited to form a CIGS layer in a second stage. The simultaneous evaporation method always vapor-deposits four elements, but vapor-deposits CIGS with Cu excess during the initial period of evaporation and CIGS with In excess during the subsequent period of evaporation.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked Se (a pre-printed collection of presentation given at the 68th Academic Lecture by the Japan Society of Applied Physics) (autumn, 2007, Hokkaido Institute of Technology), 7P-L-6, etc.);
c) Method using radicalized Se (a pre-printed collection of presentation given at the 54th Academic Lecture by the Japan Society of Applied Physics) (spring, 2007, Aoyama Gakuin Univ.), 29P-ZW-10, etc.); and
d) Method using a light excitation process (a pre-printed collection of presentation given at the 54th Academic Lecture by the Japan Society of Applied Physics) (spring, 2007, Aoyama Gakuin Univ.), 29P-ZW-14, etc.).

2) The selenization method is also called a two-stage method, whereby firstly a metal precursor formed of a laminated film such as a Cu layer/In layer, a (Cu—Ga) layer/In layer, or the like is formed by sputter deposition, vapor deposition, or electrodeposition, and the film thus formed is heated in selenium vapor or hydrogen selenide to a temperature of 450 deg C. to 550 deg C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells 35 (1994), 204-214, etc.); and a method in which selenium is sandwiched between thin metal films (e.g., as in Cu layer/In layer/Se layer Cu layer/In layer/Se layer) to form a multi-layer precursor film (T. Nakada et al., Proc. of 10th European Photovoltaic Solar Energy Conference (1991), 887-890, etc.).

An exemplary method of forming a graded band gap CIGS film is a method which involves first depositing a copper-gallium (Cu—Ga) alloy film, depositing an indium film thereon and selenizing with a Ga concentration gradient in the film thickness direction making use of natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.).

3) Known sputtering techniques include: a technique using CuInSe₂ polycrystal as a target, a technique two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and, a technique called three-source sputtering whereby a copper target, an indium target and a selenium or CuSe target are sputtered in argon gas (T. Nakada et al., Jpn. J. Appl. Phys. 32 (1993), L1169-L1172, etc.).

4) Exemplary known methods for hybrid sputtering include one in which copper and indium metals are subjected to DC sputtering in the sputtering method described above, while only selenium is vapor-deposited (T. Nakada et al., Jpn. Appl. Phys. 34 (1995), 4715-4721, etc.).

5) An exemplary method for mechanochemical processing includes a method in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming a CIGS film include screen printing, close-spaced sublimation, MOCVD, and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

While all of these formation methods exhibit a favorable photoelectric conversion efficiency as long as the temperature is 500 deg C. or more during CIGS formation on the substrate, a multisource evaporation method which has a short process time is preferred taking into consideration manufacturing using a roll-to-roll process. Above all, the bilayer method is preferred.

In this embodiment, the difference between the coefficients of linear expansion of the base 12 and the light absorbing layer 34 is preferably less than 3 ppm/K.

The linear thermal expansion coefficient of the main compound semiconductors serving as the light absorbing layer 34 is 5.8 ppm/K for GaAs, which is representative of the group III-V, 4.5 ppm/K for CdTe, which is representative of the group II-VI, and 10 ppm/K for Cu(InGa)Se₂, which is representative of the group I-III-IV.

A large thermal expansion difference between the base 12 and the light absorbing layer 34 may cause a film deposition defect such as delamination upon cooling of the compound semiconductor deposited on the substrate 10 at a high temperature of at least 500 deg C. for the light absorbing layer 34. A large internal stress of the compound semiconductor due to the difference in the thermal expansion from the base 12 may lower the photoelectric conversion efficiency of the light absorbing layer 34. A difference in the linear thermal expansion coefficient between the base 12 and the light absorbing layer 34 (compound semiconductor) of less than 3 ppm/K does not readily cause delamination or other film deposition defects, and is therefore preferred. More preferably, the difference in the linear thermal expansion coefficient is less than 1 ppm/K. The linear thermal expansion coefficient and the difference in the linear thermal expansion coefficient are obtained at room temperature (23 deg C.).

From the Young's modulus and thickness of the material that makes up the substrate 10, the thermal expansion properties of the substrate 10 are dominant in the base 12 at 10 ppm/K. Thus, the solar cell 30 that uses ferritic stainless steel for the base 12 and Cu(in Ga)Se₂ for the light absorbing layer 34 has the most preferred structure in which the linear thermal expansion coefficients of the base 12 and the light absorbing layer 34 match.

As described above, the solar cell 30 of the invention is manufactured by joining in series the thin-film solar cells 40 on the foregoing substrate 10 but may be manufactured by the same method as used to manufacture various known solar cells.

An embodiment of the method of manufacturing the solar cell 30 shown in FIG. 2 is described below.

First, the substrate 10 formed as described above is prepared. Then, the alkali supply layer 50 is formed on a surface of the insulation layer 16 of the substrate 10 by, for example, sputtering using soda-lime glass as a target, a sol-gel method using an alkoxide containing silicon (Si), sodium (Na), and calcium (Ca), or a coating and drying method using a sodium silicate aqueous solution.

Then, a molybdenum film serving as the back electrodes 32 is formed by sputtering on a surface of the alkali supply layer 50 using, for example, a film deposition apparatus.

Next, for example, laser scribing is used to scribe the molybdenum film at predetermined positions to form the spaces 33 extending in the width direction of the substrate 10. The back electrodes 32 separated from each other by the spaces 33 are thus formed.

Then, the back electrodes 32 are covered with the light absorbing layer 34 (p-type semiconductor layer) so as to fill the spaces 33. The light absorbing layer 34 is, for example, a CIGS layer and may be formed by any known film deposition method as described above.

Then, a CdS layer (n-type semiconductor layer) serving as the buffer layer 36 is formed on the CIGS layer by, for example, chemical bath deposition (CBD) method. A p-n junction semiconductor layer is thus formed.

Then, for example, laser scribing is used to scribe the thin-film solar cells 40 in the direction in which they are arranged, at predetermined positions different from those at which the spaces 33 have been formed, to thereby form the spaces 37 which extend in the width direction of the substrate 10 and reach the back electrodes 32.

Then, a layer of ZnO doped with Al, B, Ga, Sb and the like which serves as the upper electrodes 38 is formed on the buffer layer 36 by sputtering or coating so as to fill the spaces 37.

Next, for example, laser scribing is used to scribe the thin-film solar cells 40 in the direction in which they are arranged, at predetermined positions different from those at which the spaces 33 and 37 have been formed, to thereby form the spaces 39 which extend in the width direction of the substrate 10 and reach the back electrodes 32. The thin-film solar cells 40 are thus formed.

Then, the thin-film solar cells 40 formed on the rightmost and leftmost back electrodes 32 in the longitudinal direction L of the substrate 10 are removed by, for example, laser scribing or mechanical scribing to expose the back electrodes 32. Then, the first conductive member 42 and the second conductive member 44 are connected by, for example, ultrasonic soldering, onto the rightmost and leftmost back electrodes 32, respectively.

The solar cell 30 in which the thin-film solar cells 40 are electrically connected in series can be thus manufactured as shown in FIG. 2.

If necessary, a bond/seal layer, a water vapor barrier layer, and a surface protection layer are arranged on the front side of the resulting solar cell 30 and a bond/seal layer and a back sheet are formed on the back side of the solar cell 30, that is, on the back side of the substrate 10, and these layers are integrated by vacuum lamination, for example.

In the solar cell 30 of the embodiment under consideration, a bending force is repeatedly applied to the substrate by rollers and to the solar cell during manufacturing when manufacturing using a roll-to-roll process, but the occurrence of cracks and partial peeling on the anodized film serving as the insulation layer 16 and the light absorbing layer 34 is suppressed as described above, making it possible to achieve the sound solar cell 30.

Furthermore, in the solar cell 30 of the embodiment under consideration, the occurrence of cracks and partial peeling on the anodized film serving as the insulation layer 16 and the light absorbing layer 34 is suppressed as described above even when subjected to a thermal strain cycle due to differences in day and night temperatures, making it possible to maintain long-term reliability and achieve the thin-film solar cell 30 that offers excellent endurance and an excellent storage life.

While the solar cell and the solar cell manufacturing method according to the invention have been described above in detail, the invention is by no means limited to the foregoing embodiments and various improvements and modifications may of course be made without departing from the spirit of the present invention.

### Working Example 1

Next, the invention is described in further detail by referring to specific examples of the solar cell of the invention.

In Table 1 below, A to E shown in the metallic base column indicate the structure of the substrate, and the details thereof will now be described.

The following describes the metallic bases A to E, anodization, and annealing.

### Metallic Base A (Inventive Substrate)

A commercially available ferritic stainless steel (material type: SUS430) and high-purity aluminum (aluminum purity: 4N) were pressurized and bonded by cold rolling to prepare a two-layer clad material including a base 12 (ferritic stainless steel) with a reduced thickness of 50 micrometers and an Al layer 14 with a reduced thickness of 30 micrometers. The clad metallic base was thus obtained.

The back surface (opposite from the Al layer 14) and the end surfaces of the base 12 in the two-layer clad material were then covered with a masking film. Next, ultrasonic cleaning was performed using ethanol, anodization was performed under the anodization conditions indicated in Table 1 as described later to form the insulation layer 16 (anodized film), and annealing was performed under the annealing conditions indicated in Table 1 as necessary to obtain; the substrates 10 of Test Nos. A-1 to A-17 that are indicated in Table 1 and composed of the base 12, the Al layer 14, and the insulation layer 16. After the formation of the insulation layer 16, the thickness of the Al layer 14 was reduced to 20 to 25 micrometers, depending on the conditions of anodization.

### Metallic Base B (Inventive Substrate)

A commercially available ferritic stainless steel (material type: SUS447J1) and high-purity aluminum (aluminum purity: 4N) were pressurized and bonded by cold rolling to prepare a two-layer clad material including a base 12 (stainless steel) with a reduced thickness of 50 micrometers and an Al layer 14 with a reduced thickness of 30 micrometers. The clad metallic base was thus obtained.

Similar to the metallic base A, anodization was then performed under the anodization conditions indicated in Table 1 as described later and annealing was performed under the annealing conditions indicated in Table 1 as necessary to obtain the substrates 10 with the insulation layer 16 of Test Nos. B-1 to B-6 indicated in Table 1.

### Metallic Base C (Inventive Substrate)

A commercially available austenitic stainless steel (material type: SUS304) and high-purity aluminum (aluminum purity: 4N) were pressurized and bonded by cold rolling to prepare a two-layer clad material including a base 12 (stainless steel) with a reduced thickness of 50 micrometers and an Al layer 14 with a reduced thickness of 30 micrometers. The clad metallic base was thus obtained.

Similar to the metallic base A, anodization was then performed under the anodization conditions indicated in Table 1 as described later and annealing was performed under the annealing conditions indicated in Table 1 as necessary to form the substrates 10 with the insulation layer 16 of Test Nos. C-1 to C-3 indicated in Table 1.

### Metallic Base D (Non-Inventive Substrate)

A commercially available low-carbon steel aluminum (material type: SPCC) and high-purity aluminum (aluminum purity: 4N) were pressurized and bonded by cold rolling to prepare a two-layer clad material including a base 12 (carbon steel) with a reduced thickness of 50 micrometers and an aluminum layer 14 with a reduced thickness of 30 micrometers. The clad metallic base was thus obtained.

Similar to the metallic base A, anodization was then performed under the anodization conditions indicated in Table 1 as described later and annealing was performed under the annealing conditions indicated in Table 1 as necessary to form the substrates 10 with the insulation layer 16 of Test Nos. D-1 and D-2 indicated in Table 1.

### Metallic Base E (Non-Inventive Substrate)

The metallic base E is not a two-layer clad material, but rather a metallic base that uses a high-purity aluminum (aluminum purity: 4N) having a thickness of 200 micrometers.

Similar to the metallic base A, anodization was performed under the anodization conditions indicated in Table 1 as described later and annealing was performed under the annealing conditions indicated in Table 1 as necessary to form the substrates 10 with the insulation layer 16 of Test Nos. E-1 to E-3 indicated in Table 1. Note that Test Nos. E-1 to E-3 indicated in Table 1 comprise only the Al layer 14 and the insulation layer 16.

### [Anodization]

Anodization was performed at the electrolytic solution concentration and temperature described in Table 1 by constant voltage electrolysis under a constant voltage. Each anodized film was provided with a 10 micrometers thickness by adjusting the electrolysis time.

### [Annealing]

The anodized substrate was then subjected to annealing via heating using an infrared lamp in an atmosphere. The rise in the heating temperature was standardized to 500 deg C./minute up to 400 deg C. and 100 deg C./minute at 400 deg C. or more when annealing was performed at 400 deg C. or more. Once held for a predetermined period of time, the substrate was then cooled by termination of lamp heating, at a cooling rate of 500 deg C./minute around 400 deg C. and 100 deg C./minute or less at 300 deg C. or less.

Next, the evaluation method will be described.

The Young's modulus of the anodized film was measured by creating an indent of 0.5 micrometers from the anodized film surface using a nanoindenter (Fischer Instruments: HM500H). Five points were measured and the average thereof was regarded as Young's modulus. Note that the variance in the measured values was about plus or minus 5 GPa.

The internal stress of the anodized film was then found from Young's modulus and the dimensional change of the anodized film before and after dissolution and removal of the metallic substrate portion by immersing an approximate 30-mmquare sample in methanol in which iodine was dissolved to a saturated solution. The internal stress was regarded as positive in the case of compressive stress and negative in the case of tensile stress. The measurement accuracy of the dimensions of the anodized film was plus or minus 2 micrometers and, given the aforementioned measurement variance of Young's modulus, the calculated internal stress value was assessed as including an error of about plus or minus 10%.

Note that those samples for which dimensional change could not be measured since only a fragment of the anodized film was obtained upon dissolution and removal of the metallic base are denoted by a dash (“-”) in Table 1.

To evaluate the insulation properties of the anodized film in terms of the high-temperature film formation endurance and roll-to-roll handing endurance of the compound thin-film solar cell, bending strain was applied 10 times each in two orthogonal directions using a jig having a radius of curvature of 80 mm on samples subjected to heat treatment for 30 minutes at 550 deg C. using an infrared lamp in a vacuum so that the insulation layer formed a convex surface.

The insulation properties were measured upon providing via mask deposition an Au layer having a thickness of 0.2 micrometers and a diameter of 3.5 mm on the surface of the insulation layer 16 serving as electrodes, and then applying 200 V of a voltage having negative polarity to the Au electrodes. The leak current density was then found by dividing the leak current by the Au electrode surface area (9.6 mm²). This measurement was performed on nine Au electrodes provided on the same substrate, and the average thereof was regarded as the leak current density of the substrate.

A leak current density of 1×10⁻⁶ A/cm² or less with no insulation breakdown on any of the nine electrodes upon application of the 200 V was assessed as acceptable (“O”), and any other state was assessed as unacceptable (“X”).

### Result

Those test samples that used a two-layer clad material of ferritic stainless steel and Al and were electrolyzed at 50 deg C. or more or were subjected to annealing even if electrolyzed at less than 50 deg C. were found not to have any leak current abnormalities and therefore unproblematic in terms of insulation properties.

Only one test, Test No. A-8, was found to have insulation breakdown in one of the nine measurements. Upon observation of the cross-section, a compound layer of about 15 micrometers was found to exist at the interface between the stainless steel and Al, and many crack-shaped voids were confirmed at the interface between the Al and compound layer. Further, cracked sections were found in the thickness direction of the anodized film as well. Thus, the cracks presumably occurred in the anodized film due to the cracks or excessive compressive stress produced at the interface between the stainless steel and Al, causing a partial loss in insulation properties.

Heat treatment similar to annealing was performed using the aforementioned metallic bases A, B, and D, which are clad metallic bases. Examples of the results of the clad metallic substrate A are shown in FIG. 3 and FIG. 4. In each of the examples, a crack-shaped void was found at the interface between the Al and compound layer when a compound layer exceeding 10 micrometers was formed. Thus, a compound layer thickness of up to 10 micrometers is preferred.

Note that the molar compositions of the compound layer for the clad metallic bases A, B, and D are Al:Fe:Cr=3:0.8:0.2, 3:0.7:0.3, and 3:1.0:0, respectively, and the Cr presumably dissolves in the Fe site in a case of a stainless steel close to the representative Al—Fe intermetallic compound Al₃Fe. Molar ratios of Fe:Cr=8:2 and 7:3 substantially match the Fe:Cr molar ratios of SUS430 and SUS447J1, respectively, of the used stainless steel.

In addition, the temperature and holding time at which the compound layer produced at the interface between the stainless steel or soft steel and Al reaches 10 micrometers were found and, given a temperature Y (deg C) and a time X (minutes), can be expressed as Y=670−72.5 Log x, Y=683−72.5 Log x, and Y=580−72.5 Log x for the clad metallic bases A, B, and D, respectively, as shown in FIG. 4. The clad material interface reaction is thus determined by temperature and time, and a heat history not limited to annealing preferably involves conditions milder than those expressed by the aforementioned equations, and the formation conditions of the compound semiconductor serving as the light absorbing layer of the solar cell are also preferably the same.

In Table 1, in the comparison examples (Test Nos. C-1 to C-3) that used the clad metallic base C, breakdown occurred even if the anodized film was one with compressive stress. This is due to the excessively large difference in linear thermal expansion coefficient that occurred with the anodized film. The effect of this linear thermal expansion coefficient is also evident in failure to evaluate the internal stress before and after annealing due to the cracks that already occurred when annealing at 400 deg C., as indicated by Test No. C-2.

In the comparison examples (Test Nos. D-1 and D-2) that used the clad metallic base D, breakdown occurred even if the anodized film was one with compressive stress. These examples showed many cracks at the interface with the reactive layer. The cracks occurred due to the severe reaction between the soft steel and Al described earlier and the already thick compound layer formed as a result of a heat history of 550 deg C.×30 minutes, which is equivalent to the conditions for forming the compound semiconductor serving as the light absorbing layer. Moreover, the anodized layer itself also had a large number of cracks, leading to poor surface flatness. This presumably caused breakdown at a voltage of 200 V or less.

In the comparison examples (Test Nos. E-1 to E-3) that used the metallic base E as well, cracks were formed, deteriorating the flatness of the anodized film as well. Similar to the case where the clad metallic base D was employed, breakdown presumably originated from the cracks. This is also evident in the fact that the internal stress could not be evaluated before and after annealing due to the cracks that already occurred when annealing at 200 deg C., as indicated by Test No. E-2.

TABLE 1

| | | | | | | | | | | Leak Current after |
|---|---|---|---|---|---|---|---|---|---|---|
| | | | Anodization Conditions | | | | | | | Heat Treatment |
| | Working/ | | | Solution | | Annealing Conditions | | Young's | Internal | (550° C. for |
| Test | Comparison | Metallic | Electrolytic | Temperature | Voltage | Temperature | Time | Modulus | Stress | 30 min) + |
| No. | Example | Base | Solution | (° C.) | (V) | (° C.) | (Minutes) | (GPa) | (MPa) | Bending Test |
| A-1 | Working | A | 0.5M oxalic | 55 | 40 | — | — | 68 | 6 | ∘ |
| | example | | acid | | | | | | | |
| A-2 | Working | A | 1M malonic | 50 | 80 | — | — | 89 | 12 | ∘ |
| | example | | acid | | | | | | | |
| A-3 | Working | A | 1M malonic | 80 | 80 | — | — | 82 | 25 | ∘ |
| | example | | acid | | | | | | | |
| A-4 | Working | A | 1M tartaric | 80 | 120 | — | — | 92 | 97 | ∘ |
| | example | | acid | | | | | | | |
| A-5 | Working | A | 1M tartaric | 80 | 160 | — | — | 85 | 82 | ∘ |
| | example | | acid | | | | | | | |
| A-6 | Working | A | 0.5M oxalic | 16 | 40 | 100 | 30 | 118 | 45 | ∘ |
| | example | | acid | | | | | | | |
| A-7 | Working | A | 0.5M oxalic | 16 | 40 | 200 | 10 | 118 | 89 | ∘ |
| | example | | acid | | | | | | | |
| A-8 | Working | A | 0.5M oxalic | 16 | 40 | 400 | 10 | 118 | 165 | ∘ |
| | example | | acid | | | | | | | |
| A-9 | Working | A | 0.5M oxalic | 16 | 40 | 600 | 2 | 118 | 360 | ∘ |
| | example | | acid | | | | | | | |
| A-10 | Comparison | A | 0.5M oxalic | 16 | 40 | 600 | 10 | 118 | 366 | x |
| | example | | acid | | | | | | | |
| A-11 | Working | A | 1M sulfuric | 35 | 15 | 200 | 10 | 65 | 57 | ∘ |
| | example | | acid | | | | | | | |
| A-12 | Working | A | 1M sulfuric | 35 | 15 | 400 | 10 | 65 | 111 | ∘ |
| | example | | acid | | | | | | | |
| A-13 | Working | A | 1M malonic | 80 | 80 | 200 | 10 | 79 | 55 | ∘ |
| | example | | acid | | | | | | | |
| A-14 | Working | A | 1M malonic | 80 | 80 | 400 | 10 | 79 | 101 | ∘ |
| | example | | acid | | | | | | | |
| A-15 | Comparison | A | 0.5M oxalic | 35 | 40 | — | — | 85 | 2 | x |
| | example | | acid | | | | | | | |
| A-16 | Comparison | A | 1M sulfuric | 35 | 15 | — | — | 63 | −6 | x |
| | example | | acid | | | | | | | |
| A-17 | Comparison | A | 1M malonic | 35 | 80 | — | — | 75 | −5 | x |
| | example | | acid | | | | | | | |
| B-1 | Working | B | 0.5M oxalic | 55 | 40 | — | — | 83 | 7 | ∘ |
| | example | | acid | | | | | | | |
| B-2 | Working | B | 0.5M oxalic | 16 | 40 | 400 | 10 | 120 | 162 | ∘ |
| | example | | acid | | | | | | | |
| B-3 | Working | B | 0.5M oxalic | 16 | 40 | 600 | 2 | 120 | 358 | ∘ |
| | example | | acid | | | | | | | |
| B-4 | Working | B | 0.5M oxalic | 16 | 40 | 600 | 10 | 120 | 354 | ∘ |
| | example | | acid | | | | | | | |
| B-5 | Working | B | 1M sulfuric | 35 | 15 | 400 | 10 | 65 | 105 | ∘ |
| | example | | acid | | | | | | | |
| B-6 | Working | B | 1M malonic | 35 | 80 | 400 | 10 | 75 | 90 | ∘ |
| | example | | acid | | | | | | | |
| C-1 | Comparison | C | 0.5M oxalic | 55 | 40 | — | — | 75 | 17 | x |
| | example | | acid | | | | | | | |
| C-2 | Comparison | C | 0.5M oxalic | 16 | 40 | 200 | 10 | 118 | 201 | x |
| | example | | acid | | | | | | | |
| C-3 | Comparison | C | 0.5M oxalic | 16 | 40 | 400 | 10 | 118 | — | x |
| | example | | acid | | | | | | | |
| D-1 | Comparison | D | 0.5M oxalic | 55 | 40 | — | — | 75 | 9 | x |
| | example | | acid | | | | | | | |
| D-2 | Comparison | D | 0.5M oxalic | 16 | 40 | 400 | 10 | 118 | 240 | x |
| | example | | acid | | | | | | | |
| E-1 | Comparison | E | 0.5M oxalic | 55 | 40 | — | — | 75 | 11 | x |
| | example | | acid | | | | | | | |
| E-2 | Comparison | E | 0.5M oxalic | 16 | 40 | 100 | 30 | 118 | 142 | x |
| | example | | acid | | | | | | | |
| E-3 | Comparison | E | 0.5M oxalic | 16 | 40 | 200 | 10 | 118 | — | x |
| | example | | acid | | | | | | | |

The following describes the solar cells.

### [Preparation of Solar Cells]

The metallic bases A to E were used to prepare solar cells. The first reference code of each test number in Table 2 is the test number of Table 1, and indicates the kind of metallic base A to E, anodization conditions, and annealing conditions.

First, using soda-lime glass (mass composition; SiO₂: 72%, Na₂O: 13%, CaO: 8%, MgO: 5%, Al₂O₃: 2%) as the target, each test sample was sputtered in an Ar—O₂ environment at room temperature to form a 0.2 micrometers thick alkali supply layer 50 made of soda-lime glass on the surface of the insulation layer 16 of the substrate 10. Molybdenum was then sputtered on the top surface of the alkali supply layer 50 in an argon atmosphere at room temperature to form a 0.8 micrometers Mo layer, thus obtaining a substrate including the insulation layer 16 having the Mo layer formed thereon. The Mo layer was patterned in a predetermined shape to form back electrodes 32 made of molybdenum.

Then, CIGS was deposited by three-stage evaporation using a K-cell and a bilayer method to form a CIGS film with a thickness of 2 micrometers which had an average composition of CuIn_{0.7}Ga_{0.3}Se₂ and served as the light absorbing layer 34.

In the three-stage evaporation technique, the substrate was treated at the first stage at a temperature of 400 deg C. for 20 minutes. Then, at the second stage and the third stage, the substrate was treated at the same temperature for the same time, as described in Table 2.

In the bi-layer technique, the substrate was treated at the first stage and the second stage at the same temperature for the same time, as described in Table 2.

CdS was deposited by CBD method on the thus formed light absorbing layer 34 (CIGS film) to form the buffer layer 36 with a thickness of 50 nm and non-doped ZnO was sputtered as a window layer to a thickness of 50 nm, and the surfaces of the back electrodes 32 were further partially exposed by scribing.

Al-doped ZnO was further sputtered to form the upper electrodes 38 with a thickness of 500 nm and the surfaces of the back electrodes 32 were partially exposed by scribing to obtain a CIGS solar cell (module-type solar cell) of a 16 series connection structure having a cell size of 5.0 mm×90 mm and an effective area of 72 cm².

Next, the solar cell evaluation method will be described.

### [Evaluation of Solar Cells]

A solar simulator was used to irradiate the solar cells prepared with light corresponding to AM 1.5 to calculate the output density from the resulting maximum power and effective area. The output density was divided by the light intensity (1 kW/m²) at the sample surface to obtain the photoelectric conversion efficiency. This photoelectric conversion efficiency was measured twice in the state of the solar cell as is and with bending strain applied 10 times each in two orthogonal directions using a jig having a radius of curvature of 80 mm so that the light absorbing layer formed a convex surface. These photoelectric conversion efficiency measurement results are indicated in the “Before Bending Test” column and the “After Bending Test” column of Table 2, respectively.

The surface state of the light absorbing layer 34 (CIGS layer) of each solar cell was observed upon formation by an optical microscope. The results are shown in Table 2.

TABLE 2

| | | | Film Formation | Film Formation | Photoelectric | | |
|---|---|---|---|---|---|---|---|
| | | | Temperature (° C.) | Time (Minutes) | Conversion Efficiency | | |
| | | CIGS | Three-stage Method: | | Before | After | Film Formation |
| Test | Used | Formation | Second and Third Stages | | Bending | Bending | State of Light |
| No. | Substrate | Method | Bilayer Method: First and Second Stages | | Test (%) | Test (%) | Absorbing Layer |
| A1-1 | A-1 (working | Three-Stage | 500 | 10 | 12.5 | 12.5 | No abnormalities |
| | example) | Method | | | | | |
| A1-2 | A-1 (working | Bilayer | 500 | 10 | 10.5 | 10.6 | No abnormalities |
| | example) | Method | | | | | |
| A1-3 | A-1 (working | Three-Stage | 550 | 10 | 16.2 | 16.1 | No abnormalities |
| | example) | Method | | | | | |
| A1-4 | A-1 (working | Bilayer | 550 | 10 | 15.7 | 15.5 | No abnormalities |
| | example) | Method | | | | | |
| A1-5 | A-1 (working | Three-Stage | 575 | 10 | 16.5 | 15.5 | No abnormalities |
| | example) | Method | | | | | |
| A1-6 | A-1 (working | Bilayer | 575 | 10 | 16.3 | 16.2 | No abnormalities |
| | example) | Method | | | | | |
| A1-7 | A-1 (working | Three-Stage | 575 | 5 | 13.2 | 13.3 | No abnormalities |
| | example) | Method | | | | | |
| A1-8 | A-1 (working | Bilayer | 575 | 5 | 16.0 | 16.2 | No abnormalities |
| | example) | Method | | | | | |
| A14-1 | A-14 (working | Three-Stage | 575 | 10 | 16.3 | 15.1 | No abnormalities |
| | example) | Method | | | | | |
| A14-2 | A-14 (working | Bilayer | 575 | 10 | 16.5 | 16.4 | No abnormalities |
| | example) | Method | | | | | |
| B6-1 | B-6 (working | Three-Stage | 575 | 10 | 16.7 | 16.6 | No abnormalities |
| | example) | Method | | | | | |
| B6-2 | B-6 (working | Bilayer | 575 | 10 | 16.6 | 16.6 | No abnormalities |
| | example) | Method | | | | | |
| B6-3 | B-6 (working | Three-Stage | 575 | 5 | 13.0 | 13.1 | No abnormalities |
| | example) | Method | | | | | |
| B6-4 | B-6 (working | Bilayer | 575 | 5 | 16.3 | 16.2 | No abnormalities |
| | example) | Method | | | | | |
| C1-1 | C-1 (comparison | Three-Stage | 550 | 10 | 9.1 | 1.9 | Partial spot-shaped |
| | example) | Method | | | | | delamination |
| C1-2 | C-1 (comparison | Bilayer | 550 | 10 | 7.5 | 2.7 | Partial spot-shaped |
| | example) | Method | | | | | delamination |
| D1-1 | D-1 (comparison | Three-Stage | 500 | 10 | 9.0 | 6.2 | No abnormalities |
| | example) | Method | | | | | |
| D1-2 | D-1 (comparison | Bilayer | 500 | 10 | 7.8 | 6.7 | No abnormalities |
| | example) | Method | | | | | |
| D1-3 | D-1 (comparison | Three-Stage | 550 | 10 | 2.5 | — | Cracks and partial |
| | example) | Method | | | | | spot-shaped |
| | | | | | | | delamination |
| E1-1 | E-1 (comparison | Three-Stage | 500 | 10 | — | — | ⅓ or more |
| | example) | Method | | | | | delaminated |
| E1-2 | E-1 (comparison | Bilayer | 500 | 10 | — | — | ⅓ or more |
| | example) | Method | | | | | delaminated |

As shown in Table 2, the solar cells in the working examples of the invention had good conversion efficiency of 10% or more and the light absorbing layer 34 exhibited a good surface state. In addition, the photoelectric conversion efficiency increased with the film formation temperature. Upon comparison of cases having a total film formation time of 20 minutes at a high temperature, the same photoelectric conversion efficiency was found to be achieved for both the three-stage method and the bilayer method at a formation temperature of 550 deg C. or more. While the photoelectric conversion efficiency decreased with a shorter formation time and the same formation temperature in the three-stage method, substantially the same photoelectric conversion efficiency was achieved in the bilayer method. Thus, taking into consideration insulation properties after the aforementioned high-temperature heat history, the bilayer method is preferred as the formation method over the three-stage method.

Test Nos. A1-5 and A14-1 were found to exhibit a significant decrease in the photoelectric conversion efficiency after the bending test. This is not only because of the on-the-margin heat history presumed by the results of the aforementioned insulation property evaluation, but also because of the 20 minute heat history at 400 deg C. in the first stage of the three-stage method and the additional 10 minutes heat history at 400 deg C. for annealing with Test No. A14-1. Observation of the cross-section of A14-1 confirmed that an approximate 12 micrometers compound layer exists at the interface between the stainless steel and Al, and a crack-shaped void exists across a wide range at the interface between the compound layer and Al. Therefore, the possibility exists that micro-cracks occur on the anodized layer and the light absorbing layer after the bending test.

On the other hand, Test No. B6-1 having the same light absorbing layer formation conditions was not found to exhibit a significant decrease in photoelectric conversion efficiency after the bending test. This is because the SUS447J1 of the stainless steel employed has a higher heat resistance than SUS430 (low reactivity with Al).

The test samples that used the austenite stainless steel SUS304 for the clad metallic base (Test Nos. C1-1 and C1-2) were found to exhibit light absorbing layer formation abnormalities, a decrease in photoelectric conversion efficiency, and an even further decrease in photoelectric conversion efficiency after the bending test. This is due to the excessively large difference in the linear thermal expansion coefficients between the anodized film and light absorbing layer.

The test samples that used soft steel for the clad metallic base (Test Nos. D1-1 and D1-2) were not found to have any outer appearance abnormalities when formed at 500 deg C., but exhibited a decrease in photoelectric conversion efficiency, and an even further decrease in photoelectric conversion efficiency after the bending test. This is because soft steel has a lower heat resistance than stainless steel.

Those test samples that used Al (aluminum) for the metallic base (Test Nos. E1-1 and E1-2) cannot form light absorbed layer the start at 500 deg C., and the photoelectric conversion efficiency could not be measured.

Note that the solar cells of the working examples and comparison examples were evaluated using a module cell of a 16-series connection structure, and thus the generated voltage was about 10 V even when the photoelectric conversion efficiency was measured, and breakdown did not always occur when a crack was present in the anodized film. Furthermore, when the cell was a module cell having a large surface area and a high number of modules connected in series, the generated voltage increased, and the possibility of breakdown of the cracked anodized film increased significantly. When breakdown occurs, the generated current produces a short circuit with the metallic base, causing a loss in solar cell function or a significant decrease in power generation efficiency. Thus, the insulation evaluation of Table 1 and the results of solar cell properties of Table 2 combined clearly show the effect of this invention.

### INDUSTRIAL APPLICABILITY

The present invention may be applied to a wide variety of fields where the solar cells are used for power generating devices and the like.

### LEGEND

10 substrate
12 base
14 Al layer
16 insulation layer
30 solar cell
32 back electrodes
33, 37, 39 space
34 light absorbing layer
36 buffer layer
38 upper electrodes
40 thin-film solar cell
42 first conductive member
44 second conductive member
50 alkali supply layer

1. A solar cell of a module type, comprising:
a substrate; and
thin-film solar cells joined in series on said substrate,
wherein each of said thin-film solar cells has a light absorbing layer made of a compound semiconductor,
said substrate includes a base made of ferritic stainless steel, an aluminum layer formed on at least one surface of said base, and an insulation layer having a porous structure obtained by anodizing a surface of said aluminum layer, and
said insulation layer exhibits compressive stress at room temperature.

2. The solar cell according to claim 1, wherein the compressive stress of said insulation layer ranges from 4 MPa to 400 MPa.

3. The solar cell according to claim 2, wherein a Young's modulus of said insulation layer ranges from 50 GPa to 130 GPa.

4. The solar cell according to claim 1, wherein an alloy layer made of at least one metal of the ferritic stainless and aluminum exists in an interface between said base and said aluminum layer, and a thickness of said alloy layer ranges from 0.01 micrometers to 10 micrometers.

5. The solar cell according to claim 4, wherein said alloy layer is made of an alloy of a composition expressed by Al₃X (where X is at least one kind of element selected from Fe and Cr).

6-9. (canceled)

10. The solar cell according to claim 1, wherein said thin-film solar cells further includes back electrodes made of molybdenum, respectively, and wherein said insulation layer contain an alkali metal-containing compound, said solar cell further includes compound layers made of the alkali metal-containing compound disposed between said back electrodes and said insulation layer, or both.

11. The solar cell according to claim 10, wherein the alkali metal-containing compound is a compound made primarily of silicon oxide and containing sodium oxide.

12. A method of manufacturing a solar cell, comprising:
a first step of forming a substrate, said first step comprising: forming an aluminum layer on a surface of base made of ferritic stainless steel by pressurizing and bonding, and anodizing said aluminum layer under a predetermined condition to form an insulation layer that exhibits compressive stress at room temperature;
a second step of forming back electrodes on said insulation layer of said substrate;
a third step of forming light absorbing layers made of a compound semiconductor on said back electrodes at a film deposition temperature of 500 deg C. or more, respectively; and
a fourth step of forming upper electrodes on said light absorbing layers, respectively.

13. The method of manufacturing a solar cell according to claim 12, further comprising a step of allowing Na to contain into said insulation layer layer between said first step and said second step.

14. The method of manufacturing a solar cell according to claim 12, wherein said anodizing step is achieved by electrolysis in an electrolytic solution of a temperature of 50 deg C. or more, said electrolytic solution having an acid dissociation constant of 2.5 to 3.5 at a temperature of 25 deg C.

15. A method of manufacturing a solar cell, comprising:
a first step of forming a substrate, said first step comprising: forming a aluminum layer on a surface of base made of a ferritic stainless steel by pressurizing and bonding, anodizing said aluminum layer to form a first insulation layer, and subjecting the thus formed first insulation layer to a heat treatment at a heating temperature of 600 deg C. or less to form a second insulation layer that exhibits compressive stress at room temperature;
a second step of forming back electrodes on said insulation layer of said substrate, respectively;
a third step of forming light absorbing layers made of a compound semiconductor on said back electrodes at a film deposition temperature of 500 deg C. or more, respectively; and
a fourth step of forming upper electrodes on said light absorbing layers, respectively.

16. The method of manufacturing a solar cell according to claim 15, wherein a heat treatment condition of said heat treatment subjecting step comprises a heating temperature of 100 to 600 deg C. and a holding time of 1 second to 10 hours.

17. The method of manufacturing a solar cell according to claim 15, wherein said substrate includes said base, said aluminum layer formed on said base and said insulation layer formed on said aluminum layer, and said heat treatment is performed in an atmosphere containing an oxygen.

18-19. (canceled)

20. The method of manufacturing a solar cell according to claim 12, wherein the ferritic stainless steel is chrome steel that contain 17 mass % chrome, and said light absorbing layers are formed under a condition expressed as a following expression (1), when Y is a temperature (deg C) and x is a time (minutes),
Y≦670−72.5 Log x (1).

21. The method of manufacturing a solar cell according to claim 12, wherein the ferritic stainless steel is chrome steel that contain 30 mass % chrome, and said light absorbing layers are formed under a condition expressed as a following expression (2), when Y is a temperature (deg C) and x is a time (minutes),
Y≦683−72.5 Log x (2).

22. The method of manufacturing a solar cell according to claim 15, wherein said light absorbing layers comprise a CIGS compound semiconductor and said CIGS compound semiconductor is formed by vapor-phase deposition.

23. The method of manufacturing a solar cell according to claim 15, wherein said light absorbing layers are made of a CIGS compound semiconductor and said CIGS compound semiconductor is formed by first evaporating four elements Cu, In, Ga, and Se onto each of said back electrodes, and in a following second phase, evaporating three elements In, Ga, and Se, excluding Cu.

24. The method of manufacturing a solar cell according to claim 15, wherein the ferritic stainless steel is chrome steel that contain 17 mass % chrome, and said light absorbing layers are formed under a condition expressed as a following expression (1), when Y is a temperature (deg C) and x is a time (minutes),
Y≦670−72.5 Log x (1).

25. The method of manufacturing a solar cell according to claim 15, wherein the ferritic stainless steel is chrome steel that contain 30 mass % chrome, and said light absorbing layers are formed under a condition expressed as a following expression (2), when Y is a temperature (deg C) and x is a time (minutes),
Y≦683−72.5 Log x (2).
